(19) United States
(12) Patent Application Publication
(10) Pub. No.: US 2010/0096011 A1
(43) Pub. Date: Apr. 22, 2010

(54) HIGH EFFICIENCY INTERFEROMETRIC COLOR FILTERS FOR PHOTOVOLTAIC MODULES

(75) Inventors: Jonathan C. Griffiths, Fremont, CA (US); Manish Kothari, Cupertino, CA (US)

Correspondence Address: KNOBBE, MARTENS, OLSON & BEAR, LLP, 2040 MAIN STREET, FOURTEENTH FLOOR, IRVINE, CA, 92614, US

(73) Assignee: QUALCOMM MEMS Technologies, Inc., San Diego, CA (US)

(21) Appl. No.: 12/356,437

(22) Filed: Jan. 20, 2009

Related U.S. Application Data
(60) Provisional application No. 61/106,058, filed on Oct. 16, 2008.
(60) Provisional application No. 61/139,839, filed on Dec. 22, 2008.

(51) Int. Cl. H01L 31/00; H01L 31/0232; G02B 27/14

(52) U.S. Cl. 136/257; 438/72; 359/839; 257/E31.127

(57) ABSTRACT

Devices incorporating an interferometric stack configured to reflect a certain color and transmit longer wavelengths through the interferometric stack. In one example, a color filtering includes two partial reflectors comprising an extinction coefficient that is less than about one at wavelengths greater than about 800 nm. The two partial reflectors define an optical resonant cavity forming an interferometric stack configured to reflect color and transmit some electromagnetic waves. In another example, a photovoltaic device includes two photovoltaic active layers that act as partial reflectors to form an interferometric stack. The photovoltaic device is configured to reflect color and produce power.

### CROSS-REFERENCE TO RELATED APPLICATIONS

This application claims the benefit of U.S. Provisional Application No. 61/106,058 filed on Oct. 16, 2008, titled “HIGH EFFICIENCY INTERFEROMETRIC COLOR FILTERS FOR PHOTOVOLTAIC MODULES,” and U.S. Provisional Application No. 61/139,839 filed on Dec. 22, 2008, titled “MONOLITHIC IMOD COLOR ENHANCED PHOTOVOLTAIC CELL,” which are hereby expressly incorporated by reference in their entireties.

### BACKGROUND OF THE INVENTION

1. Field of the Invention

The invention relates generally to the field of optoelectronic transducers that convert optical energy into electrical energy, for example, photovoltaic cells.

2. Description of the Related Art

For over a century fossil fuel such as coal, oil, and natural gas has provided the main source of energy in the United States. The need for alternative sources of energy is increasing. Fossil fuels are a non-renewable source of energy that is depleting rapidly. The large scale industrialization of developing nations such as India and China has placed a considerable burden on the available fossil fuel. In addition, geopolitical issues can quickly affect the supply of such fuel. Global warming is also of greater concern in recent years. A number of factors are thought to contribute to global warming; however, widespread use of fossil fuels is presumed to be a main cause of global warming. Thus there is an urgent need to find a renewable and economically viable source of energy that is also environmentally safe. Solar energy is an environmentally safe renewable source of energy that can be converted into other forms of energy such as heat and electricity.

Photovoltaic (PV) cells convert optical energy to electrical energy and thus can be used to convert solar energy into electrical power. Photovoltaic solar cells can be made very thin and modular. PV cells can range in size from about a few millimeters to ten's of centimeters, or larger. The individual electrical output from one PV cell may range from a few milliwatts to a few watts. Several PV cells may be connected electrically and packaged in arrays to produce a sufficient amount of electricity. PV cells can be used in a wide range of applications such as providing power to satellites and other spacecraft, providing electricity to residential and commercial properties, charging automobile batteries, etc.

While PV devices have the potential to reduce reliance upon hydrocarbon fuels, the widespread use of PV devices has been hindered by inefficiency and aesthetic concerns. Accordingly, improvements in either of these aspects could increase usage of PV devices.

### SUMMARY OF THE INVENTION

Certain embodiments of the invention include photovoltaic cells or devices integrated with interferometric modulators to reflect a visible color or colors to a viewer. Such colored photovoltaic devices may be made to reflect any of a broad range of colors using light interference principles thus addressing the needs of a particular application. This may make the photovoltaic devices more aesthetically pleasing and therefore more useful in building or architectural applications.

According to one embodiment, the invention comprises a color filtering device comprising a first partial reflector layer comprising a material having an extinction coefficient that is less than about one (1) at wavelengths greater than about 800 nm, a second partial reflector layer comprising a material having an extinction coefficient that is less than about one (1) at wavelengths greater than about 800 nm, and a first optical resonant cavity defined by the first partial reflector layer and the second partial reflector layer.

According to another embodiment, the invention comprises a photovoltaic device comprising a first partial reflector layer comprising a material having an extinction coefficient that is less than about 1 at wavelengths greater than 800 nm, a second partial reflector layer comprising a photovoltaic active material, and a first optical resonant cavity defined by the first partial reflector layer and the second partial reflector layer.

According to another embodiment, the invention comprises a photovoltaic device comprising a first partial reflector layer comprising a photovoltaic active material having an extinction coefficient that is less than about 1 at wavelengths greater than 800 nm, a second partial reflector layer comprising a photovoltaic active material, and a first optical resonant cavity defined by the first partial reflector layer and the second partial reflector layer.

According to another embodiment, the invention comprises a photovoltaic device comprising a first photovoltaic active material layer, a second photovoltaic active material layer, an optical resonant cavity disposed between the first photovoltaic active material layer and the second photovoltaic active material layer, a first transparent conductive material layer disposed such that the first photovoltaic active material layer is between the first transparent conductive material layer and the optical resonant cavity, and a second transparent conductive material layer disposed such that the second photovoltaic active material layer is between the second transparent conductive material layer and the optical resonant cavity.

According to another embodiment, the invention comprises a method of manufacturing a photovoltaic device comprising depositing a first transparent conductive material layer on a substrate, depositing a first partial reflector layer on the first transparent conductive material layer, depositing a second transparent conductive material layer on the first partial reflector layer, depositing a second partial reflector layer on the second transparent conductive material layer, and depositing a third transparent conductive material layer on the second partial reflector layer.

According to another embodiment, the invention comprises a photovoltaic device comprising a first partial reflector layer comprising a photovoltaic active material having an extinction coefficient that is less than about 1 at wavelengths greater than 800 nm, a second partial reflector layer comprising a photovoltaic active material, a first optical resonant cavity defined by the first partial reflector layer and the second partial reflector layer, a reflector layer, a second optical resonant cavity comprising a transparent conductive material, the second optical resonant cavity defined by the second partial reflector layer and the reflector layer, and a transparent conductive material layer disposed such that the first partial reflector layer is between the transparent conductive material layer and the first optical resonant cavity.

According to another embodiment, the invention comprises a photovoltaic device comprising a color filter comprising a first partial reflector and a transparent conductive material layer disposed on the first partial reflector and a photovoltaic active material layer disposed on the transparent conductive material layer.

According to another embodiment, the invention comprises a method of manufacturing a photovoltaic device comprising providing a starter stack having a front side and a back side, the starter stack comprising a first partial reflector and depositing a photovoltaic active layer on the back side of the starter stack. In one aspect, the starter stack may comprise a transparent conductive material layer disposed such that the first partial reflector is between the transparent conductive material layer and the front side of the starter stack. In another aspect, the starter stack may comprise a transparent conductive material layer and spacer layer disposed such that the transparent conductive material layer and spacer layer are between the partial reflector and the back side of the starter stack.

### BRIEF DESCRIPTION OF THE DRAWINGS

Example embodiments disclosed herein are illustrated in the accompanying schematic drawings, which are for illustrative purposes only. The drawings are not drawn to scale, unless otherwise stated as such, or necessarily reflect relative sizes of illustrated aspects of the embodiments.

FIG. 1 schematically illustrates a theoretical optical interferometric cavity.

FIG. 2A schematically illustrates an interferometric modulator (IMOD) including two partial reflector layers and a spacer layer.

FIG. 2B is a block diagram of an IMOD, similar to that of FIG. 2A, including two partial reflector layers and a spacer layer.

FIG. 2C schematically illustrates an IMOD where the spacer layer includes an air gap formed by posts or pillars between the partial reflector layers.

FIG. 2D shows total reflection versus wavelength of an IMOD with a spacer layer configured to have a peak wavelength reflectance of approximately 540 nm (yellow) for normally incident and reflected light.

FIG. 3A schematically illustrates a photovoltaic cell comprising a p-n junction.

FIG. 3B is a block diagram that schematically illustrates a photovoltaic cell comprising a deposited thin film photovoltaic active material.

FIGS. 3C and 3D are schematic plan and isometric sectional views, respectively, depicting an exemplary solar photovoltaic device with visible reflective electrodes on the front side.

FIG. 4A is a block diagram that schematically illustrates an interferometric modulator stack.

FIGS. 4B-4I are block diagrams that schematically illustrate photovoltaic cells comprising interferometric modulator stacks.

FIG. 5A is a diagram showing the spectral responses of various photovoltaic materials at various wavelengths.

FIG. 5B is a diagram showing the spectral response of a silicon photovoltaic cell.

FIG. 5C is a diagram showing the transmission of light energy as a function of wavelength through an interferometric stack configured as shown in FIG. 4A with a 50 Å molybdenum first partial reflector, an 1800 Å optical resonant cavity comprising silicon dioxide, and a 60 Å aluminum second partial reflector.

FIG. 5D is a diagram showing the reflection of light energy as a function of wavelength from the substrate side of an interferometric modulator configured as shown in FIG. 4A with a 50 Å molybdenum first partial reflector, an 1800 Å optical resonant cavity comprising silicon dioxide, and a 60 Å aluminum second partial reflector.

FIG. 5E is a chromaticity diagram depicting the color reflected from the substrate side of an interferometric stack configured as shown in FIG. 4A with a 70 Å amorphous silicon first partial reflector, a 1500 Å optical resonant cavity comprising silicon dioxide, and a 70 Å amorphous silicon second partial reflector.

FIG. 5F is a diagram showing the reflection of light energy as a function of wavelength from the substrate side an interferometric stack configured as shown in FIG. 4A with a 70 Å amorphous silicon first partial reflector, a 1500 Å optical resonant cavity comprising silicon dioxide, and a 70 Å amorphous silicon second partial reflector.

FIG. 5G is a diagram showing the transmission of light energy as a function of wavelength through an interferometric stack configured as shown in FIG. 4A with a 70 Å amorphous silicon first partial reflector, a 1500 Å optical resonant cavity comprising silicon dioxide, and a 70 Å amorphous silicon second partial reflector.

FIG. 5H is a diagram showing the upper and lower transmission values of light energy through an interferometric stack configured as shown in FIG. 4A with a 70 Å amorphous silicon first partial reflector, a 70 Å amorphous silicon second partial reflector, and a first optical resonant cavity comprising silicon dioxide having a thickness that is varied from 1200 Å to 4000 Å.

FIG. 5I shows a diagram comparing the index of refractions and extinction coefficients of various materials across a range of wavelengths.

FIG. 5J shows a diagram comparing the negative change in peak output from a sample PV cell covered with an interferometric stack configured as shown in FIG. 4A as the thickness of the spacer layer is changed and as the thickness of the first and second partial reflectors are changed.

FIGS. 6A-6D illustrate embodiments of patterned interferometric modulator stacks displaying different colors in different regions to form images over a static display comprising a color PV device.

FIGS. 7A-7C are block diagrams schematically illustrating a method of manufacturing a PV device incorporating two PV cells and one IMOD.

FIGS. 7D-7E are block diagrams schematically illustrating a method of manufacturing a PV device incorporating a PV cell and an IMOD.

FIG. 7F is a block diagram illustrating an exemplary embodiment of a method of manufacturing a PV device incorporating two PV cells and one IMOD.

### DETAILED DESCRIPTION OF THE PREFERRED EMBODIMENT

One issue hindering widespread adoption of photovoltaic (PV) devices on available surfaces for conversion of light energy into electric energy or current is the difficulty of integrating them due to their color, in various applications, for example on signs, billboards, or buildings. The active PV material itself may appear dark. Some shiny conductors/electrodes may also be visible. Both of these factors can hinder the blending and use of PV devices with surrounding materials due to aesthetic concerns. Embodiments of PV cells described herein may have interferometric modulator stacks including one or more PV active material layers that act as partial reflectors to create an IMOD stack. Such embodiments can be designed to enhance reflections of select wavelength spikes or peaks in the visible range using the principles of optical interference. Reflecting selective wavelengths can cause the PV cell to appear a certain color to a viewer. Thus, the PV cell can be designed to appear a certain color according to the needs of a particular application. The interferometric reflection or transmission is governed by the dimensions and fundamental material properties of the materials making up the interferometric modulator stack. Accordingly, the coloring effect is not as susceptible to fading over time compared to common dyes or paints.

Although certain embodiments and examples are discussed herein, it is understood that the inventive subject matter extends beyond the specifically disclosed embodiments to other alternative embodiments and/or uses of the invention and obvious modifications and equivalents thereof. It is intended that the scope of the inventions disclosed herein should not be limited by the particular disclosed embodiments. Thus, for example, in any method or process disclosed herein, the acts or operations making up the method/process may be performed in any suitable sequence and are not necessarily limited to any particular disclosed sequence. Various aspects and features of the embodiments have been described where appropriate. It is to be understood that not necessarily all such aspects or features may be achieved in accordance with any particular embodiment. Thus, for example, it should be recognized that the various embodiments may be carried out in a manner that achieves or optimizes one feature or group of features as taught herein without necessarily achieving other aspects or features as may be taught or suggested herein.

The following detailed description is directed to certain specific embodiments of the invention. However, the invention can be embodied in a multitude of different ways. The embodiments described herein may be implemented in a wide range of devices that incorporate photovoltaic devices for conversion of optical energy into electrical current. For example, it is contemplated that the embodiments may be implemented in billboards, signs, architectural structures, in solar panels placed on or around residential structures, commercial buildings, and vehicles including boats and cars.

In this description, reference is made to the drawings wherein like parts are designated with like numerals throughout. As will be apparent from the following description, the embodiments may be implemented in a variety of devices that comprise photovoltaic active material.

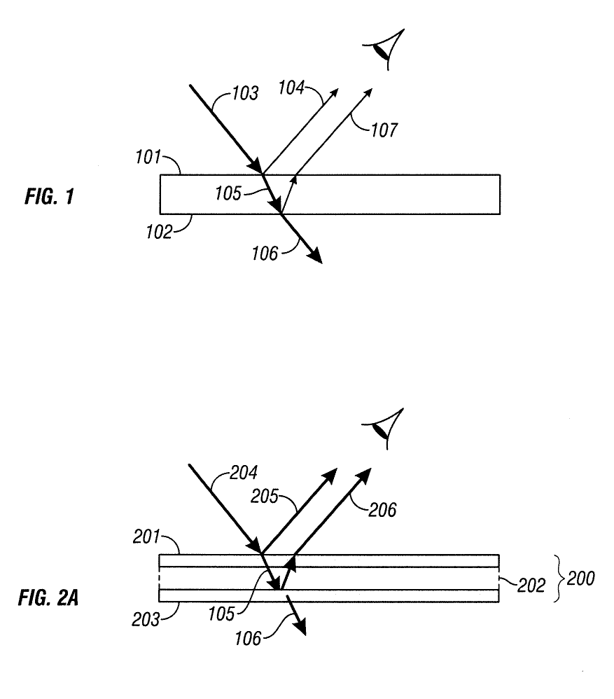

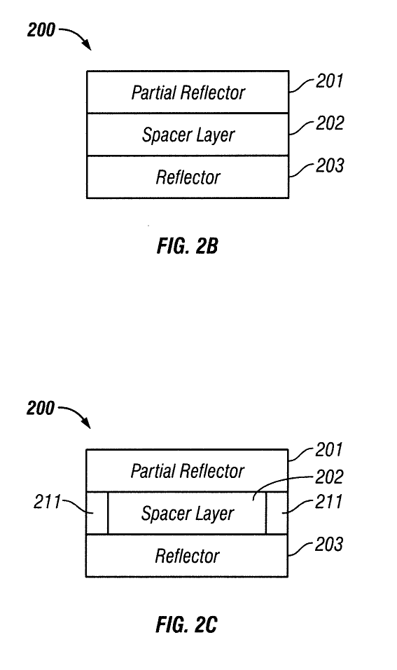

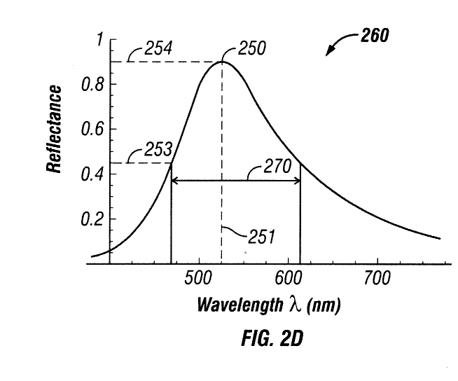

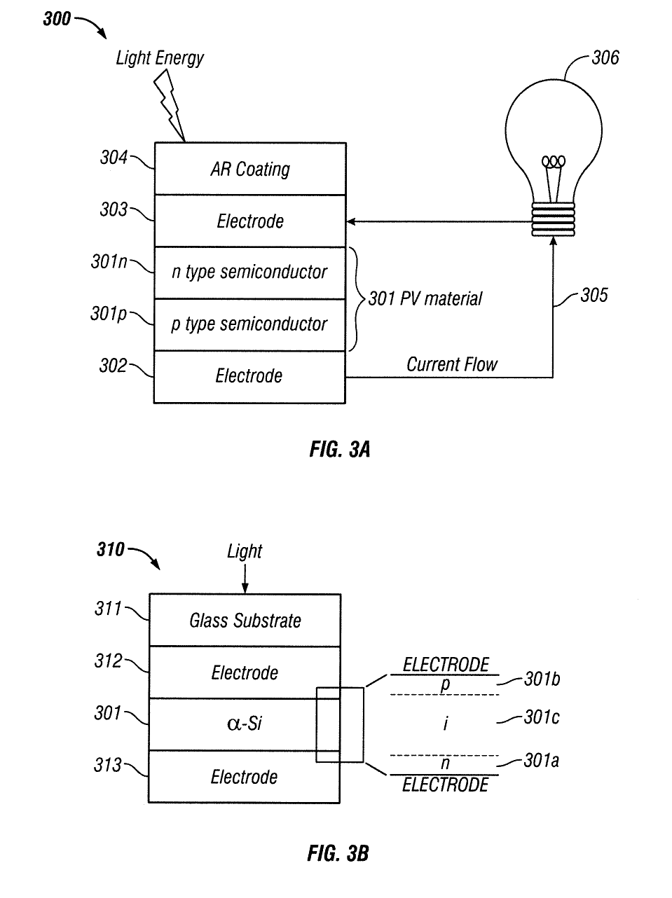

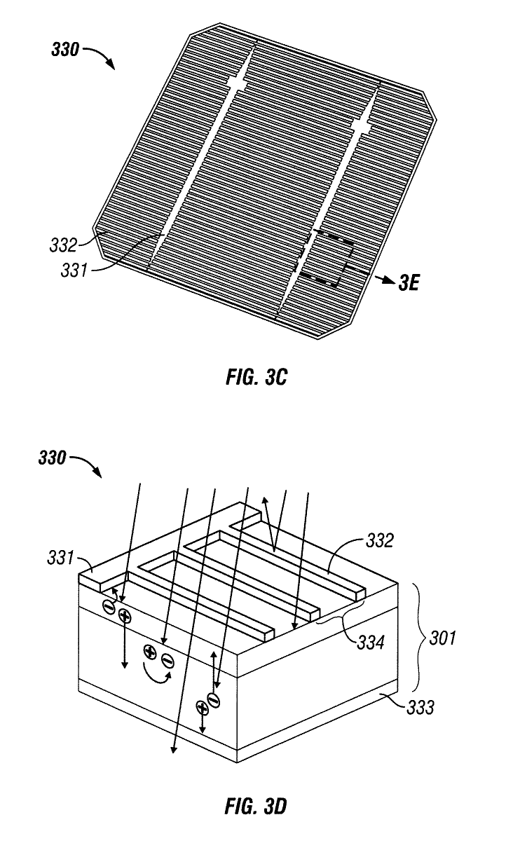

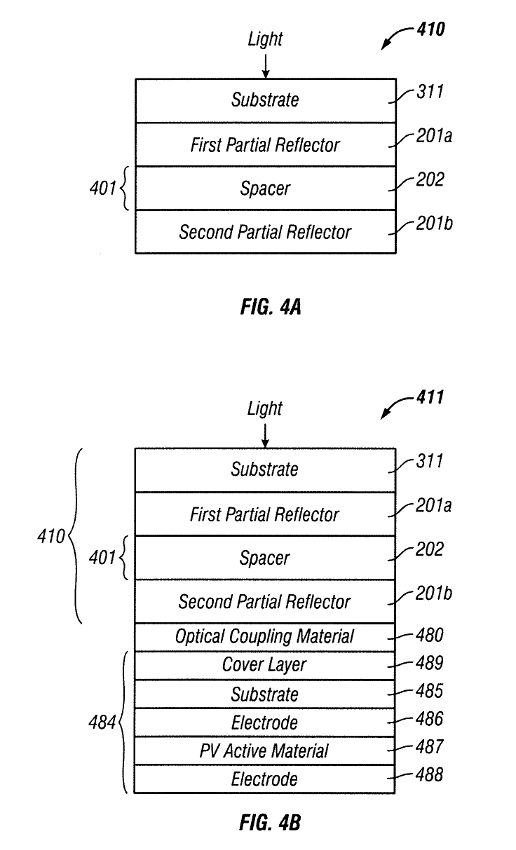

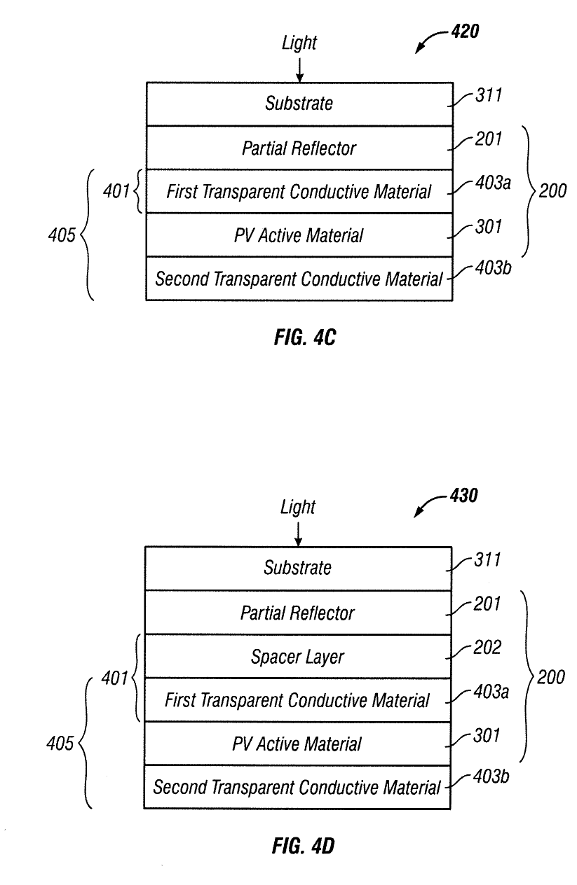

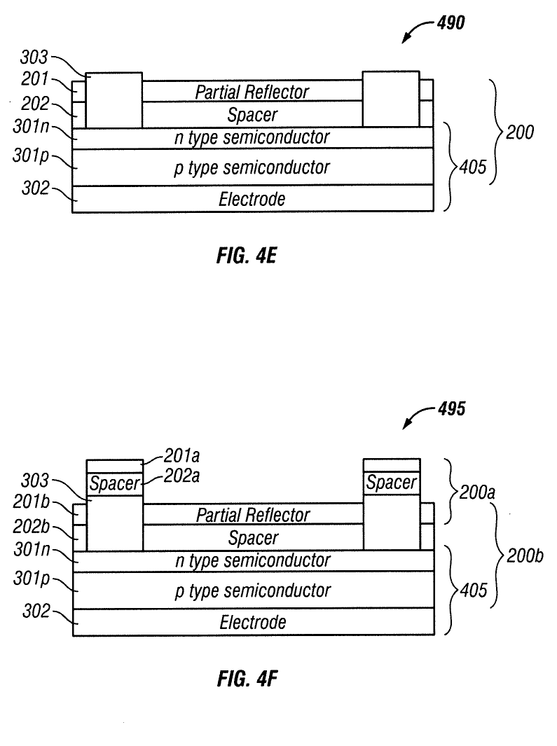

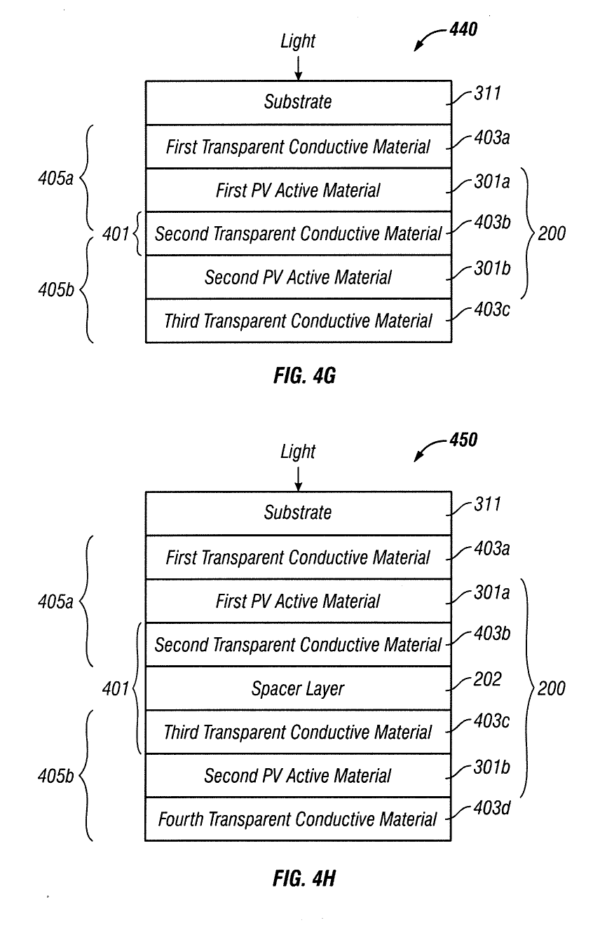

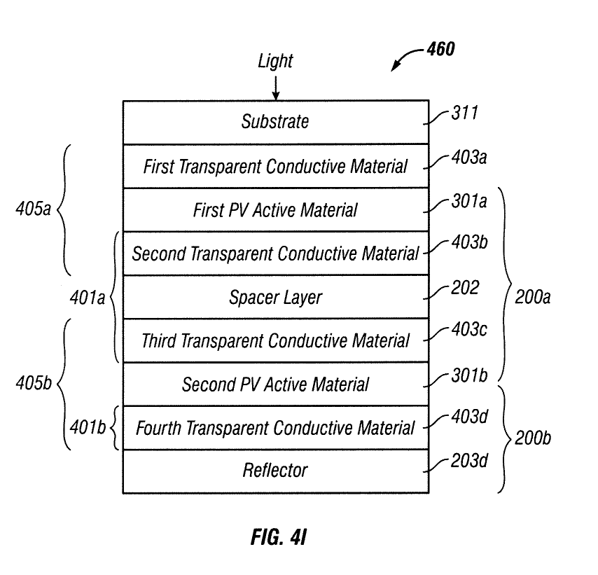

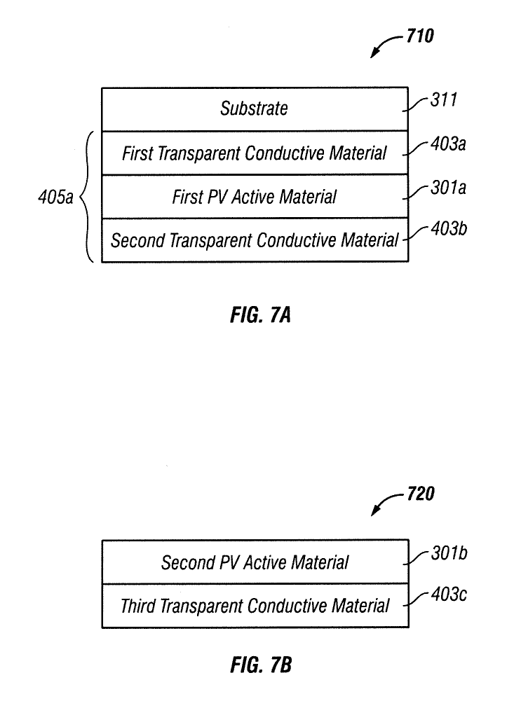

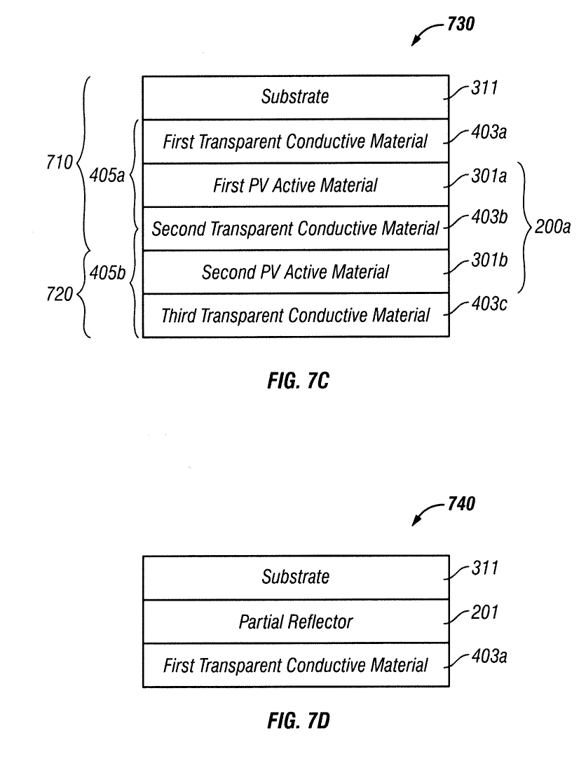

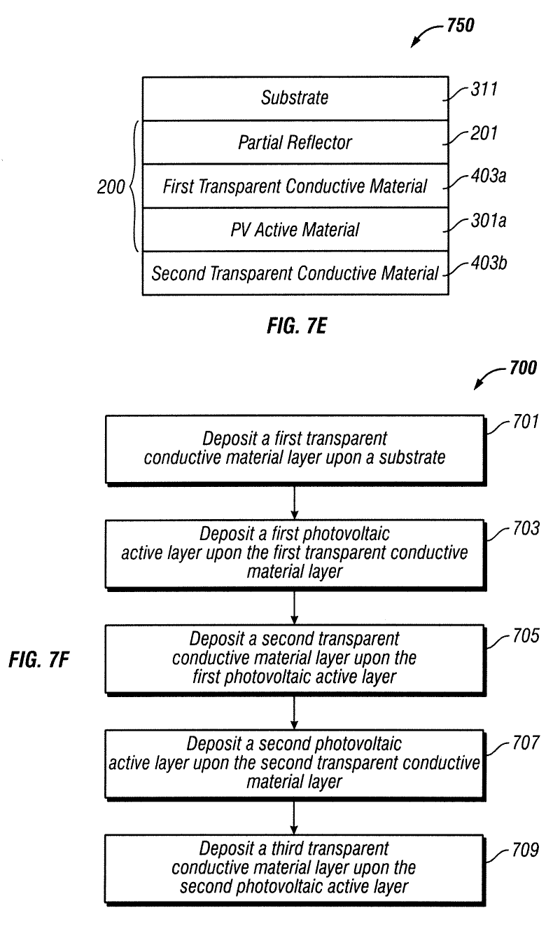

Initially, FIGS. 1-2D illustrate some optical principles and different embodiments of IMODs that are useful for integrating with photovoltaic devices, as described with respect to FIGS. 4A-7D. FIGS. 3A-3D illustrate embodiments of photovoltaic device constructions with integrated IMOD stacks. FIGS. 4A-6D illustrate embodiments in which interferometric modulators are integrated with photovoltaic devices, and properties of these embodiments. FIGS. 7A-7D illustrate embodiments of methods of forming photovoltaic devices that incorporate an IMOD stack.

FIG. 1 is a schematic illustrating an embodiment of an optical resonant cavity. A particular example of such an optical resonant cavity is a soap film which may produce a spectrum of reflected colors. An optical resonant cavity is a structure that can be used to interferometrically manipulate light. The optical resonant cavity shown in FIG. 1 comprises upper and lower interfaces 101 and 102, defining a space or volume therebetween. The two interfaces 101 and 102 may be opposing surfaces on the same layer. For example, the two interfaces 101 and 102 may comprise surfaces on a glass or plastic plate or sheet or a film of glass, plastic, or any other transparent material. Air or other media may surround the plate, sheet, or film. The optical resonant cavity may have one material on one side of it at the upper interface 101, and a separate (e.g., different) material on the other side at the lower interface 102. The materials forming interfaces 101, 102 with the optical resonant cavity may be a metallic or partially reflecting layer, a transparent media, or a dielectric, for example, air. Materials forming interfaces 101, 102 with the optical resonant cavity may be the same, or may be different. In the illustrated embodiment, light partially reflects and partially transmits at each of the interfaces 101, 102.

Still referring to FIG. 1, a ray of light 103 that is incident on the front surface 101 of the optical resonant cavity is partially reflected as indicated by the light path 104 and partially transmitted through the front surface 101 along light path 105. Ray 103 may have a broad spectral distribution of light. For example, ray 103 may comprise white light, and therefore may have significant components from a broad range of wavelengths within the visible range, 450 nm to 700 nm, as well as wavelengths outside the visible range. The transmitted light ray 105 may be partially reflected along light path 107 and partially transmitted out of the resonant cavity along light path 106. The optical properties, including the thickness, of the optical resonant cavity, as well as the properties of the surrounding materials may affect both the amplitude and phase of light reflected from both interface 101 and interface 102. Therefore, rays 104 and 107 will each have an amplitude and a phase, depending on the properties of the optical resonant cavity, and the surrounding media. The example is simplified by omission of multiple internal reflections, as will be appreciated by the skilled artisan.

Still referring to FIG. 1, for purposes of the discussions provided herein, the total intensity of light reflected from the optical resonant cavity is a coherent superposition of the two reflected light rays 104 and 107. With such coherent superposition, both the amplitude and the phase of the two reflected beams contribute to the aggregate intensity. This coherent superposition is referred to as interference. The two reflected rays 104 and 107 may have a phase difference with respect to each other. In some embodiments, the phase difference between the two waves may be 180 degrees (180°) and cancel each other out. If the phase and the amplitude of the two light rays 104 and 107 are configured so as to reduce the intensity at a particular wavelength then the two light beams are referred to as interfering destructively at that wavelength. If on the other hand the phase and the amplitude of the two light beams 104 and 107 are configured so as to increase the intensity at a particular wavelength then the two light rays are referred to as interfering constructively at that wavelength. The phase difference depends on the optical path difference of the two paths, which depends both on the thickness of the optical resonant cavity, the index of refraction of the material between the two interfaces 101 and 102, and whether the indices of surrounding materials are higher or lower than the material forming the optical resonant cavity. The phase difference is also different for different wavelengths in the incident beam 103. Accordingly, rays 104 and 107 may have a phase difference relative to each other, and this phase difference may vary with wavelength. Thus, some wavelengths may interfere constructively and some wavelengths may interfere destructively. In general, the colors and the total intensity reflected and transmitted by the optical resonant cavity thus depend on the thickness and the material forming the optical resonant cavity and surrounding media. The reflected and transmitted wavelengths also depend on viewing angle, different wavelength being reflected and transmitted at different angles.

Still referring to FIG. 1, the principles described above can be used to construct structures that will interferometrically selectively reflect and/or transmit wavelength spectra or range(s) of visible wavelengths of incident light depending on the wavelength of the light. A structure which affects the reflection or transmission of light depending on its wavelength using the principles of interference can be referred to as an interferometric modulator stack, or more simply an interferometric modulator. In some embodiments, the interferometric modulator (IMOD) includes an optical resonant cavity that is formed between two partial reflectors. In other embodiments, the IMOD includes an optical resonant cavity that is formed between a partial reflector and a full reflector. In embodiments where a full reflector is used to define an optical resonant cavity, the IMOD may not be transmissive. In embodiments where two partial reflectors are used to define an optical resonant cavity, the IMOD may be transmissive. Alternatively, the stack may only include one partial reflector and a spacer layer and another reflector, a partial or full reflector, can be provided separately to form an IMOD. In this scenario the spacer layer is an optically resonant layer and the optical resonant cavity is formed between the first partial reflector and the second reflector when the second reflector is placed on the spacer layer. Other layer(s) having their own functions in the underlying devices may also serve as a partial or composite reflector. As will be appreciated by the skilled artisan, where the optical path length for light reflected from the interferometric stack is on about the same order of magnitude as the visible wavelength, the visual effect can be quite stark. As the optical path length increases and exceeds the coherence length of white light (e.g., 5000 nm and above), interference is no longer possible as the phase of the light loses its coherence so that the visual interferometric color effect is lost.

FIG. 2A depicts an embodiment of an interferometric modulator 200. The IMOD 200 includes a partial reflector layer 201, a spacer layer 202, and a reflector layer 203. Reflector layer 203 may be a second partial reflector layer or a full reflector, here it is depicted as a partial reflector. In FIG. 2A, the spacer layer 202 is sandwiched between two reflective surfaces. In this particular embodiment, the partial reflector layer 201 defines the top of an optical resonant cavity which comprises spacer layer 202 while a bottom reflector layer 203 defines the bottom of the optical resonant cavity. The reflector layer 203 may include a single layer or multiple layers of material which affect its reflectance. The thickness of the partial reflector layer 201 and reflector 203 layers may be selected to control relative amounts of reflectance and transmittance of light. Both the partial reflector layer and reflector layer may comprise metal, and both can be configured to be partially transmissive. For example, the reflector layer 203 may comprise a partial reflector that is configured to transmit and reflect light. As shown in FIG. 2A, the ray of light 204 that is incident on the partial reflector layer 201 of the optical interference cavity may be partially reflected out of the optical interference cavity along each of the paths 205 and 206. The illumination field as viewed by an observer on the front or incident side is a superposition of the two reflected rays 205 and 206. The amount of light substantially reflected 206 by the bottom reflector 203 or transmitted 106 through the bottom reflector 203 can be significantly increased or reduced by varying the thickness and the composition of the reflector layers, whereas the apparent color of reflections is largely determined by the interference effect governed by the size or thickness of the spacer layer 202 and the material properties of the partial reflector layer 201 that determine the difference in optical path length between the rays 205 and 206. Modulating the bottom reflector thickness 203 (or omitting in favor of whatever reflectivity is provided by an interface between the spacer layer 202 and an underlying medium) will modulate the intensity of the reflected color versus the overall reflectivity of the IMOD 200 and thus influence the intensity of transmissions 106 through the IMOD 200.

Still referring to FIG. 2A, in some IMODs, the spacer layer 202 comprises a solid layer, for example, an optically transparent dielectric layer, or plurality of layers. In other IMODs, the spacer layer 202 comprises an air gap or combination of optically transparent layer(s) and an air gap. The thickness of the spacer layer 202 may be tuned to maximize or minimize the reflection of one or more specific colors of the incident light. The color or colors reflected by the optical interference cavity may be changed by changing the thickness of the spacer layer. Accordingly, the color or colors reflected by the optical interference cavity may depend on the thickness of the spacer layer 202.

FIG. 2B is a simplified schematic of an embodiment of an IMOD 200. As illustrated, the IMOD 200 comprises a partial reflector 201, a partial or full reflector 203, and spacer layer 202 between the partial reflector 201 and the reflector 203. The material chosen for the partial reflector 201 may be selected by the extinction coefficient, κ, for the particular material. The extinction coefficient for a particular substance is a measure of how well it scatters and absorbs electromagnetic radiation, as defined by Equation 1 (below). If electromagnetic waves can pass through a material very easily, the material has a low extinction coefficient. On the other hand, if the electromagnetic waves cannot penetrate a material, and become “extinct” or “die out” within the material, the extinction coefficient is high.

$$κ = \frac{λ}{4 π} α \qquad [ Equation 1 ]$$

In Equation 1, the extinction coefficient of a particular material is represented by κ, the absorption coefficient of that material is represented by α, and λ represents the vacuum wavelength of the electromagnetic wave (not the wavelength of the electromagnetic wave in the material). As can be seen by Equation 1, the extinction coefficient, κ, is directly related to the product of the absorption coefficient, α, and the wavelength of the electromagnetic wave in a vacuum, λ. The partial reflector 201 may comprise various materials, for example, photovoltaic materials, molybdenum (Mo), titanium (Ti), tungsten (W), and chromium (Cr), as well as alloys, for example, MoCr. The thickness of the partial reflector may be between about 20 and 300 Å. The reflector 203 may, for example, comprise a photovoltaic material or a metal layer, for example, aluminum (Al), silver (Ag), molybdenum, gold (Au), or chromium, Cr, etc., and may be thick enough to be opaque (e.g., 300 nm). In other IMODs, the reflector 203 is a partial reflector and may be as thin as 20 Å. Generally, the thickness of a reflector 203 that is a partial reflector will be between about 20 and 300 Å. The spacer layer 202 may comprise an air gap and/or one or more optically transparent materials. The spacer layer 202 may be defined by a single layer of material disposed between the reflector 203 and the partial reflector 201. In such embodiments, the material may include an optically resonant material, for example, a transparent conductor or transparent dielectric. Exemplary transparent materials for the spacer layer 202 may comprise dielectrics, for example, silicon dioxide (SiO₂), titanium dioxide (TiO₂), magnesium fluoride (MgF₂), chromium (III) oxide (Cr₃O₂), and silicon nitride (Si₃N₄), as well as transparent conductive materials including transparent conductive polymers and transparent conductive oxides (TCOs), for example, indium tin oxide (ITO), zinc oxide (ZnO), etc. More generally, any dielectric with an index of refraction (n) between 1 and 3 may form a suitable spacer layer. In situations where a conductive color IMOD stack is required, the spacer layer 202 may comprise conductive transparent films. In some IMODs, the spacer layer 202 can comprise a composite structure comprising multiple materials that may include two or more of an air gap, a transparent conducting material, for example, a transparent conductive oxide, and a transparent dielectric layer. A possible function of multiple layers and/or air gaps is that selected layers of the stack may serve multiple functions, for example, device passivation or scratch resistance in addition to its optical role in the IMOD 200. In some embodiments, the spacer layer 202 may comprise one or more partially transparent materials, whether conductive or dielectric.

With reference to FIG. 2C, in other embodiments the thickness of the spacer layer 202 may comprise an air gap 202 supported by spacers 211, for example, rails, posts or pillars. Within the IMOD 200, the spacer layer 202 may be an air gap that is static, or one that is dynamic, e.g., variable using, for example, MEMS technology.

Still referring to FIG. 2C, an interferometric modulator structure 200 such as shown in FIG. 2B or 2C selectively produces a desired reflection output using optical interference. This reflected output may be “modulated” by selection of the thickness and optical properties of a static spacer layer 202, as well as the thickness and optical properties of the partial reflector 201 and the reflector 203 in all or portions of IMOD 200. The color observed by a viewer viewing the surface of the partial reflector 201 will correspond to those frequencies that are substantially reflected out of the IMOD 200 and are not substantially absorbed or destructively interfered by the various layers of the IMOD 200. The frequencies that interfere and are not substantially absorbed can be varied by selecting the thickness of the spacer layer 202.

FIG. 2D illustrates a graph of reflectance of an IMOD (for example, the IMOD 200 of FIG. 2B) versus wavelength as seen from a direction normal or perpendicular to the front surface of the interferometric stack, according to one embodiment. This graph depicts the wavelength spectrum of the reflected light which may generally be different from the wavelength spectrum of the light incident on the IMOD. In the illustrated graph, the reflectance is maximized around a peak 250 of approximately 540 nm. Hence, the peak wavelength 251 is approximately 540 nm (yellow). Peak 250 also has a half-peak bandwidth, which is the width of the peak at a reflectance 253 equal to half of the peak or maximum reflectance 254. In other embodiments, the location of the peak of the total reflection curve can be shifted by changing the thickness or material of the spacer layer 202, or by changing the material and thickness of one or more layers in the IMOD, or both. The location of the peak wavelength reflectance 250 may depend on viewing angle. As illustrated, there is only one peak; however, there may be multiple peaks of different amplitude depending on the height or thickness of the spacer layer. As will be known to one of skill in the art, the IMOD may also be configured to modulate absorption or transmittance as well as reflectance.

FIG. 3A shows a photovoltaic (PV) cell 300. A photovoltaic cell can convert light energy into electrical energy or current. A PV cell is an example of a renewable source of energy that has a small carbon footprint and has less impact on the environment. Using PV cells can reduce the cost of energy generation. PV cells can have many different sizes and shapes, e.g., from smaller than a postage stamp to several inches across. Several PV cells can often be connected together to form PV cell modules that may be up to several feet long and a few feet wide. Modules, in turn, can be combined and connected to form PV arrays of different sizes and power output.

Still referring to FIG. 3A, the size of an array can depend on several factors, for example, the amount of sunlight available in a particular location and the needs of the consumer. The modules of the array can include electrical connections, mounting hardware, power-conditioning equipment, and batteries that store solar energy for use when the sun is not shining. A PV device can be a single cell with its attendant electrical connections and peripherals, a PV module, a PV array, or solar panel. A PV device can also include functionally unrelated electrical components, e.g., components that are powered by the PV cell(s).

With reference to FIG. 3A, a PV cell includes a PV active region 301 comprising PV material disposed between two electrodes 302, 303. In some embodiments, the PV cell comprises a substrate on which a stack of layers is formed. The PV active layer of a PV cell may comprise a semiconductor material, for example, silicon. In some embodiments, the PV active region 301 may comprise a p-n junction formed by contacting an n-type semiconductor material 301n and a p-type semiconductor material 301p as shown in FIG. 3A. Such a p-n junction may have diode-like properties and may therefore be referred to as a photodiode structure as well.

Still referring to FIG. 3A, the PV active region 301 is sandwiched between two electrodes that provide an electrical current path. The back electrode 302 can be formed of aluminum, silver, or molybdenum or some other conducting material. The back electrode can be rough and unpolished. The front electrode 303 may be designed to cover a significant portion of the front surface of the p-n junction so as to lower contact resistance and increase collection efficiency. In embodiments wherein the front electrode 303 is formed of an opaque material, the front electrode 303 may be configured to leave openings over the front of the PV active region to allow illumination to impinge on the PV active region. In some embodiments, the front and back electrodes can include a transparent conductor, for example, transparent conducting oxide (TCO), for example, tin oxide (SnO₂) or indium tin oxide (ITO). The TCO can provide electrical contact and conductivity and simultaneously be transparent to the incoming light. In some embodiments, the PV cell can also comprise an anti-reflective (AR) coating 304 disposed over the front electrode 303. The AR coating 304 can reduce the amount of light reflected from the front surface of the PV active material 301.

Still referring to FIG. 3A, when the front surface of the PV active material is illuminated, photons transfer energy to electrons in the active region. If the energy transferred by the photons is greater than the band-gap of the semiconducting material, the electrons may have sufficient energy to enter the conduction band. An internal electric field is created with the formation of the p-n junction. The internal electric field operates on the energized electrons to cause these electrons to move, thereby producing a current flow in an external circuit 305. The resulting current flow can be used to power various electrical devices, for example, a light bulb 306 as shown in FIG. 3A.

The PV active material layer(s) shown in FIG. 3A can be formed by any of a variety of light absorbing, photovoltaic materials, for example, crystalline silicon (c-silicon), amorphous silicon (α-silicon), cadmium telluride (CdTe), copper indium diselenide (CIS), copper indium gallium diselenide (CIGS), light absorbing dyes and polymers polymers dispersed with light absorbing nanoparticles, III-V semiconductors, for example, GaAs, etc. Other materials may also be used. The light absorbing material(s) where photons are absorbed and transfer energy to electrical carriers (holes and electrons) is referred to herein as the PV active layer or material of the PV cell, and this term is meant to encompass multiple active sub-layers. The material for the PV active layer can be chosen depending on the desired performance and the application of the PV cell.

Still referring to FIG. 3A, in some arrangements, the PV cell can be formed by using thin film technology. For example, in one embodiment, where optical energy passes through a transparent substrate, the PV cell may be formed by depositing a first or front electrode layer of TCO on a substrate. PV active material may be deposited on the first electrode layer. A second electrode layer can be deposited on the layer of PV active material. The layers may be deposited using deposition techniques, for example, physical vapor deposition techniques, chemical vapor deposition techniques, electro-chemical vapor deposition techniques, etc. Thin film PV cells may comprise amorphous, monocrystalline or polycrystalline materials, for example, thin-film silicon, CIS, CdTe or CIGS. Thin film PV cells facilitate small device footprint and scalability of the manufacturing process.

FIG. 3B is a block diagram schematically illustrating an embodiment of a thin film PV cell 310. The PV cell 310 includes a glass substrate 311 through which light can pass. Disposed on the glass substrate 311 are a first electrode layer 312, a PV active layer 301 (shown as comprising amorphous silicon), and a second electrode layer 313. The first electrode layers 312 can include a transparent conducting material, for example, ITO. As illustrated, the first electrode layer 312 and the second electrode layer 313 sandwich the thin film PV active layer 301 therebetween. The illustrated PV active layer 301 comprises an amorphous silicon layer. As is known in the art, amorphous silicon serving as a PV material may comprise one or more diode junctions. Furthermore, an amorphous silicon PV layer or layers may comprise a p-i-n junction wherein a layer of intrinsic silicon 301c is sandwiched between a p-doped layer 301b and an n-doped layer 301a. A p-i-n junction may have higher efficiency than a p-n junction. In some other embodiments, the PV cell can comprise multiple junctions.

FIGS. 3C and 3D illustrate a PV device 330. As illustrated, the PV device 330 comprises front electrodes 331, 332 formed over a semiconductor wafer, for example, a silicon wafer. However, as will be appreciated from descriptions below, other PV devices may comprise a thin film photovoltaic material. PV devices including either thin film or wafer-type PV material can be interferometrically-enhanced (see FIG. 4A and attendant description). As illustrated in FIGS. 3C and 3D, PV devices employ specular or reflective conductors on a front, or light-incident, side of the device as well as on a back side of the PV device 330. Conductors on the front or light-incident side can comprise bus electrodes 331 or gridline electrodes 332. When optical energy is absorbed by the PV active material, electron-hole pairs are generated. These electrons and holes can generate current by moving to one or the other of the front electrodes 331, 332 or back electrodes 333, as shown in FIG. 31). The front conductors or electrodes 331, 332 are patterned to both reduce the resistance of the path an electron or hole must travel to reach an electrode while also allowing enough light to pass through to the PV active region 301. The patterns of the front electrodes 331, 332 may include windows 334 to allow incident light to propagate to the PV active material. While the PV device 330 is illustrated with front conductors or electrodes 331, 332 patterned and back electrodes 333 as unpatterned, those of skill in the art will understand that the back conductors or electrodes may also be patterned in a different manner. The front and back electrodes 331, 332, 333 may comprise reflecting metallic conducting material. In some embodiments, the front and back electrodes 331, 332, 333 may include transparent conductive materials, for example, ITO, or both transparent and reflective conducting materials.

Still referring to FIGS. 3C and 3D, traditionally, the appearance of PV cells is dictated by the material comprising the electrodes and PV active material of the PV cells. However as the use of PV cells becomes more ubiquitous and new applications for PV cells emerge, designing and manufacturing colored PV cells may become important. Such colored cells may increase visual appeal and add aesthetic value. For example, there has been a lot of interest in designing and manufacturing building integrated PV applications (BIPV). The ability to pattern or blanket color on PV devices can aid in the acceptance of PV cells deployed on rooftops and facades of buildings, billboards, cars, electronic equipment apparel, shoes, and many other locations that get exposed to light. Not only do IMODs provide an ability to produce durable, fade-resistant color, but they also can produce a desired intensity and attractive color while still permitting design selection of the degree of light transmission through the IMOD stack.

Alternative methods to incorporate color into a PV cell are to add dyes or pigment of the appropriate color or add colored material in the PV stack. High absorption of light by such tinting, however, reduces the efficiency of the PV cell. Moreover, the colors have a tendency to fade in a shorter time than the lifespan of the PV device, particularly since the devices are often meant to be constantly exposed to sunlight.

Accordingly, certain embodiments herein below describe “coloring” a PV cell by incorporating or integrating interferometric modulators with PV cells or devices. Using an IMOD on or as part of a PV device may allow for the appearance of a color reflecting from the IMOD hence imparting a “color” to the PV cell or device. Since the color of the reflection from an IMOD can be selected by using spacer layers of appropriate thickness and material (index of refraction), as well as by selecting and using appropriate thicknesses and materials for partial reflectors, an interferometric modulator stack incorporated with a PV cell or device can be configured to reflect colors as desired for any particular application. The interferometric color reflecting effect can be affected by the thickness and material(s) of the spacer layer as well as the thickness and material(s) of the reflector and partial reflector materials. Accordingly, the color effect is not as susceptible to fading over time compared to common dyes or paints.

FIG. 4A illustrates an embodiment of an IMOD stack 410 configured to reflect a color and optimize transmission of wavelengths in the infrared through the first partial reflector layer. The stack 410 comprises an optical resonant cavity 401 disposed between a first partial reflector layer 201a and a second partial reflector layer 201b. Both the first partial reflector layer 201a and second partial reflector layer 201b are configured to transmit and reflect light. The amount of light transmitted and reflected by the partial reflector layers 201a,b may be controlled by the thickness of the layers and/or the materials. For example, the first and second partial reflector layers 201a,b may comprise amorphous silicon with a thickness between about 20 Å and 300 Å. The material of the first and second partial reflector layers 201a,b may be chosen based on the extinction coefficient of the material. For example, the first partial reflector layer may comprise a material with a higher extinction coefficient in the visible light spectrum than the infrared spectrum in order to facilitate reflection of visible light and transmission of infrared electromagnetic waves. Examples of materials with higher extinction coefficients in the visible light spectrum than the infrared spectrum include Ge, GaInP, α-Si, CdTe, GaAs, InP, polycrystalline silicon, monocrystalline silicon, ZnO, and CIGS. The first and second partial reflectors 201a,b may be identical or different. For example, the first and second partial reflectors 201a,b may each contain a 20 Å layer of amorphous silicon. Alternatively, the partial reflectors may comprise different materials.

Still referring to FIG. 4A, the optical resonant cavity 401 may comprise a spacer layer 202. The spacer layer 202 may comprise any optically resonant material, for example, air or a transparent conductive material. The thicknesses of the spacer layer 202 and optical resonant cavity 401 may be tuned to reflect a certain color from the IMOD 410 based on the principles of interference. Additionally, the stack 410 may comprise a substrate layer 311 through which light can pass. The first partial reflector layer 201a may be disposed upon the substrate layer 311. The substrate layer 311 may comprise a glass, polymer, or similar substrate. The IMOD stack 410 may be added to objects to make those objects appear to be a certain color based on the color reflected from the IMOD stack 410. For example, an IMOD stack 410 may be placed over a photovoltaic cell to make the photovoltaic cell appear a certain color. The IMOD stack 410 may be transmissive in order to transmit electromagnetic waves to underlying objects, for example, photovoltaic cells. In one embodiment, the IMOD stack 410 may be configured to be more transmissive at certain wavelengths than at others. In some embodiments, the IMOD stack 410 may be configured to be more transmissive of infared radiation and less transmissive of visible light.

FIG. 4B depicts a photovoltaic device 411 comprising the IMOD stack 410 depicted in FIG. 4A coupled with a photovoltaic cell 484 such that at least some incident light can propagate through to the photovoltaic cell 484. The photovoltaic cell 484 may be a thin film photovoltaic cell similar to the device depicted in FIG. 3B or photovoltaic cell 484 may be a wafer based photovoltaic cell similar to the device depicted in FIG. 3A. The photovoltaic cell 484 may comprise a back electrode 488, a photovoltaic active material layer 487, a front electrode 486, and an optional substrate layer 485. The IMOD stack 410 is configured to reflect a certain color and optimize transmission of longer wavelengths through the second partial reflector layer 201b to the photovoltaic cell 484. The photovoltaic cell 484 may optionally be coupled to the second partial reflector layer 201b using an optical coupling material 480. The optical coupling material 480 may include an adhesive with a refractive index chosen to avoid or minimize inter-layer reflections. In other cases, the optical coupling material 480 may comprise an elastomer.

Still referring to FIG. 4B, photovoltaic device 411 may optionally comprise a cover layer 489. The cover layer 489 may comprise a substrate, for example, glass, that may be coupled to one side of the photovoltaic cell 484 or IMOD stack 410. An optical coupling material 480 may be used to couple the cover layer 489 with the second partial reflector layer 201b or substrate layer 311 of the IMOD stack 410. The optical coupling material 480 may include an adhesive with a refractive index chosen to avoid or minimize inter-layer reflections. The optical coupling material 480 may also comprise an elastomer, such as ethylene-vinyl-acetate. In another example (not shown), the IMOD stack 410 may be disposed between a cover layer 489 and the photovoltaic cell 484. An optical coupling material may be used to couple IMOD stack 410 to the cover layer 489 and to couple IMOD stack 410 to the photovoltaic cell 484. Alternatively, IMOD stack layers 201a, 202, and 201b may be directly deposited on a cover layer 489 or substrate layer 485.

FIG. 4C depicts a photovoltaic device 420 that incorporates an IMOD stack 200 to reflect a certain color light from the device 420. The device 420 comprises an optical resonant cavity 401 disposed between a partial reflector 201 and a PV active material layer 301. The partial reflector 201, optical resonant cavity 401, and PV active material layer 301 form an IMOD stack 200 configured to reflect a certain color. In the IMOD stack 200 depicted in FIG. 4B, the PV active material layer 301 acts as a second partial reflector layer configured to reflect some light and transmit some light. The optical resonant cavity 401 may comprise a first transparent conductive material layer 403a. The first transparent conductive material layer 403a operates both as an optically resonant spacer layer as well as a conducting electrode for the PV active layer 301. The device 420 may further comprise a second transparent conductive material layer 403b disposed below the PV active material layer 301 operates as a conducting electrode. The transparent conductive material layers 403a,b and the PV active material 301 comprise a thin film PV cell 405 similar to the PV device shown in FIG. 3B. The device 420 may also comprise a glass, polymer, or similar substrate layer 311 disposed over the first partial reflector 201.

Still referring to FIG. 4C, the material chosen for partial reflector layer 201 may be selected based on its extinction coefficient. For example, a material with a very low extinction coefficient at wavelengths outside of the visible spectrum may be chosen in order to maximize transmission of infrared electromagnetic waves to the PV active material 301 while reflecting a bright color. Also, the material chosen for the PV active material layer 301 may be selected by the spectral response for the particular material. For example, the PV active material 301 may comprise amorphous silicon, a material with a spectral response that generates power at longer wavelengths above the visible light spectrum. In one embodiment, both the partial reflector layer 201 and the PV active material layer 301 comprise amorphous silicon, a material with both a very low extinction coefficient at wavelengths in the infrared and a spectral response that makes good use of these longer infrared wavelengths.

FIG. 4D depicts another embodiment of a photovoltaic device 430 that incorporates an IMOD stack 200. In this embodiment, the optical resonant cavity 401 further comprises a spacer layer 202 in addition to a first transparent conductive material layer 403a. The spacer layer 202 may comprise an air gap or any other suitable optically resonant material. The PV material 301 acts as a partial reflector to form an IMOD 200 with the partial reflector layer 201 and the optical resonant cavity 401. The IMOD 200 can be configured to enhance reflections of one or more wavelength spectra within a visible wavelength by selecting certain characteristics, e.g., the thickness of the spacer layer 202, first transparent conductive material layer 403a, partial reflector 201, and PV active material 301. In some embodiments, the thickness of the spacer layer 202 combined with the first transparent conductive material layer 403a may be between about 500 Å and about 5000 Å. In some embodiments, the thicknesses of the partial reflector and PV active material layers may be between about 20 Å and about 300 Å.

FIG. 4E depicts another embodiment of a PV device 490 that incorporates an IMOD stack 200. In this embodiment, the photovoltaic cell 405 comprises a wafer based photovoltaic cell, which can be, for example, similar to the photovoltaic device depicted in FIG. 3A. The device 490 comprises an optically resonant spacer layer 202 that is disposed between a partial reflector 201 and an n-type semiconductor 301n. A p-type semiconductor 301p is disposed between a back electrode 302 and the n-type semiconductor 301b. Together, the n-type semiconductor 301n and the p-type semiconductor 301p form a composite partial reflector. IMOD 200 comprises this composite reflector and also comprises the partial reflector 201 and the spacer layer 202, which are configured to reflect some light from the partial reflector 201 side of the device 490 and transmit some light through the PV cell 405. In this embodiment, the partial reflector 201 and spacer 201 do not cover the front electrodes 303. Thus, the color of light reflected from these electrodes is not controlled.

FIG. 4F depicts another embodiment of a PV device 495 that incorporates an IMOD stack 200b similar to the PV device shown in FIG. 4E. However, in FIG. 4F, the front electrodes 303 are covered with a spacer layer 202a and a partial reflector 201a. The partial reflectors 201a, spacer layers 202a, and front electrodes 303 form an IMOD stack 200a. In this embodiment, the front electrodes 303 act as a full reflector and do not transmit any light to the PV device 405. However, as opposed to the PV device shown in FIG. 4E, the entire side of PV device 495 incident to the sun reflects a color controlled by the configuration of either IMOD 200b or IMODs 200a.

FIG. 4G depicts another embodiment of a photovoltaic device 440 that incorporates an IMOD stack 200. In this embodiment, the device 440 comprises two thin film PV cells 405a,b. The first thin film PV cell 405a comprises a first transparent conductive material layer 403a, a first PV active material layer 301a, and a second transparent conductive material layer 403b. In this embodiment, the second thin film PV cell 405b comprises the second transparent conductive material layer 403b, a second PV active material 301b, and a third transparent conductive material layer 403c. The first PV active material layer, second transparent conductive material layer, and second PV active material layer form an IMOD 200. In IMOD 200, both PV active material layers 301a,b act as partial reflectors configured to enhance reflections of one or more wavelengths of visible light. Additionally, the first and second PV active material layers 301a,b may comprise a material with a lower extinction coefficient in the infrared spectrum than the visible light spectrum. For example, the first and second PV active material layers 301a,b may comprise amorphous silicon. The second transparent conductive material layer 403b serves both as an optically resonant spacer layer within optical resonant cavity 401 as well as a conducting layer for holes and or electrons to conduct out of PV active layers 301a,b. As discussed below, the optical resonant cavity can comprise additional layers.

FIG. 4H depicts another embodiment of a photovoltaic device 450 that incorporates two thin film PV cells 405a,b. In this embodiment, PV thin film cells 405a,b each comprise PV active material layers 301a,b that define an optical resonant cavity 401 to form an IMOD 200. In contrast to FIG. 4G, in the embodiment shown in FIG. 4H, the PV thin film cells 405a,b do not share a common transparent conductive material layer and are separated by an optically resonant spacer layer 202. The optically resonant spacer layer 202 may comprise any suitable optically resonant diaelectric material, for example, silicon dioxide or other suitable optically transmissive or transparent medium. The spacer layer 202 may comprise a plurality of optically resonant layers. The thickness of the optical resonant cavity 401 may be between about 500 Å and about 5000 Å depending on the desired color reflected from substrate side of the device 450. Also, the PV active material layers 301a,b may have thicknesses between about 20 Å and about 300 Å.

FIG. 4I depicts an embodiment of a photovoltaic device 460 comprising two IMODs 200a,b. In this embodiment, the photovoltaic device 460 comprises the layers shown in FIG. 4H and further comprises a reflector layer 203 disposed below the second thin film cell 405b. The reflector layer 203 and second PV active material layer 301b define a second optical resonant cavity 401b. Optical resonant cavity 401b can comprise a fourth transparent conductive material layer 403d. The second PV active material layer 301b, fourth transparent conductive material layer 403d, and reflector layer 203, form a second IMOD 200b. The second IMOD 200b is configured to interferometrically enhance the strength of the electromagnetic field in the second PV active material layer 301b, resulting in an interferometrically enhanced PV thin film cell 405b with improved efficiency. The reflector layer 203b may comprise a partial or full reflector. The optical properties (dimensions and material properties) of the reflector layer 203b and fourth transparent conductive material layer 403d are selected so that reflection from interfaces of the layered PV thin film cell 405b coherently sum to produce an increased field of a suitable wavelength distribution and phase in the second PV active material layer 301b where optical energy is converted into electrical energy. Such interferometrically enhanced devices increase the absorption of optical energy in the active region of the interferometric photovoltaic cell and thereby increase the efficiency of device 460.

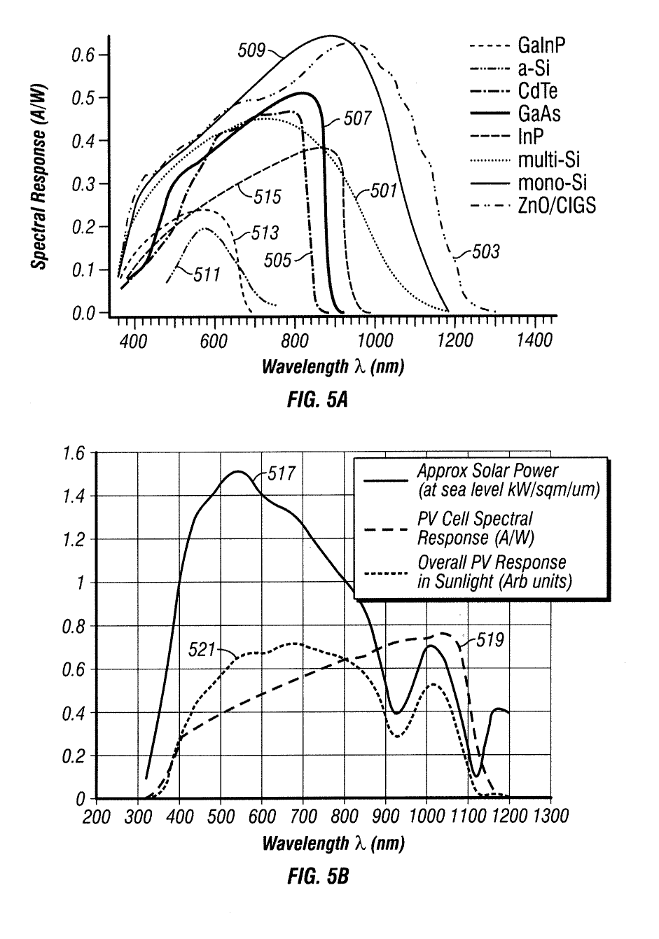

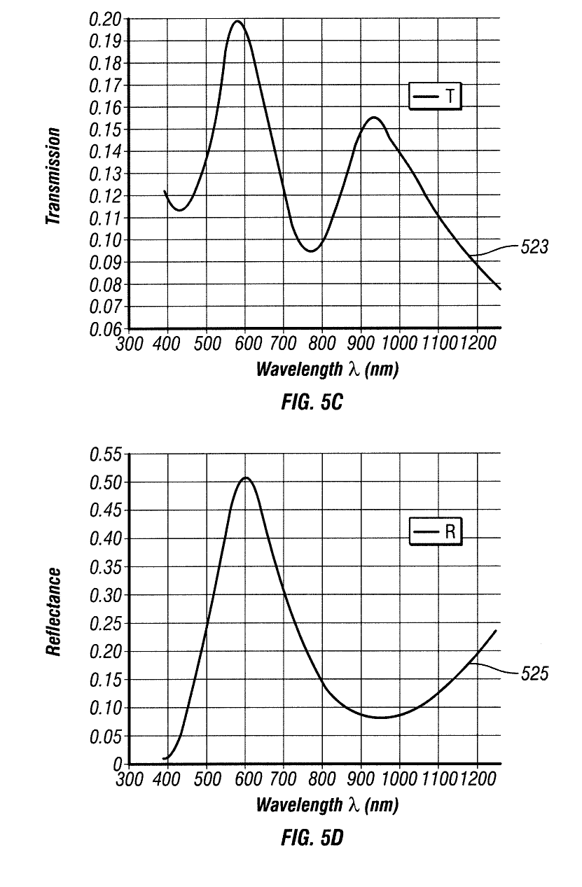

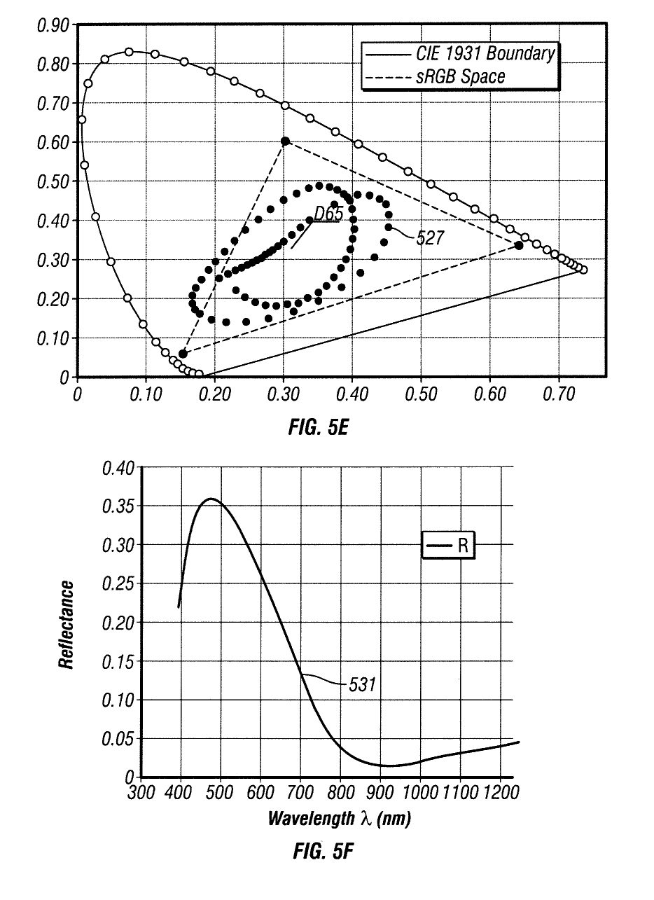

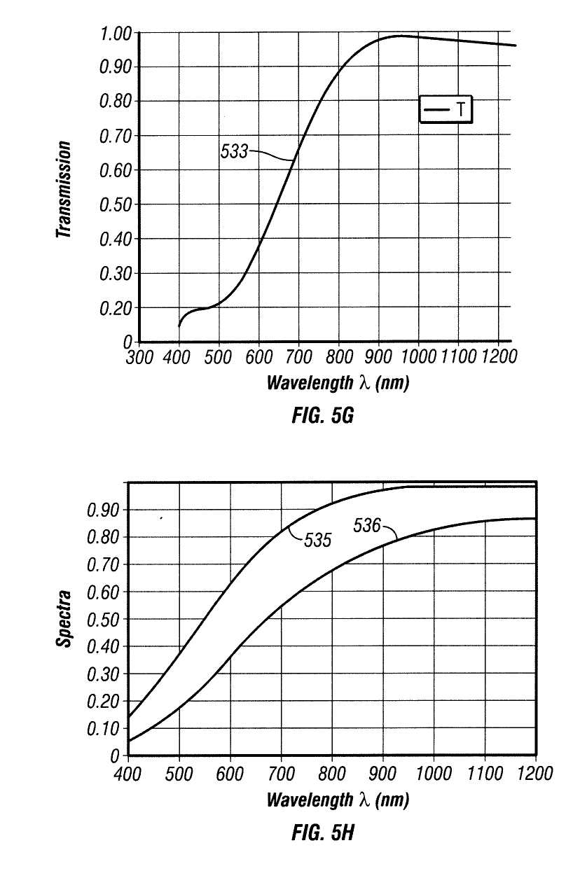

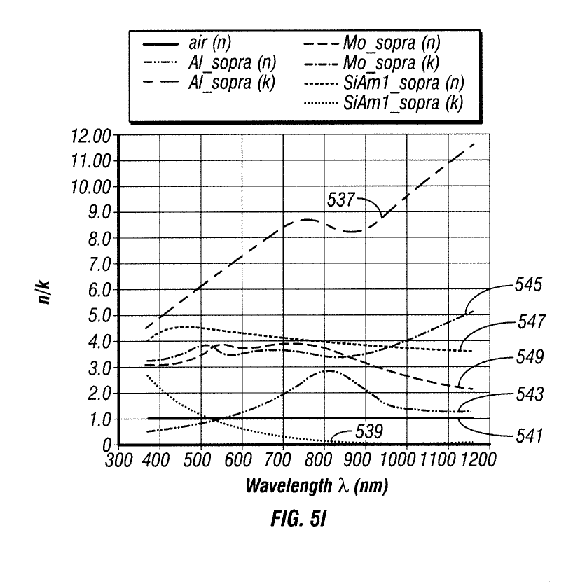

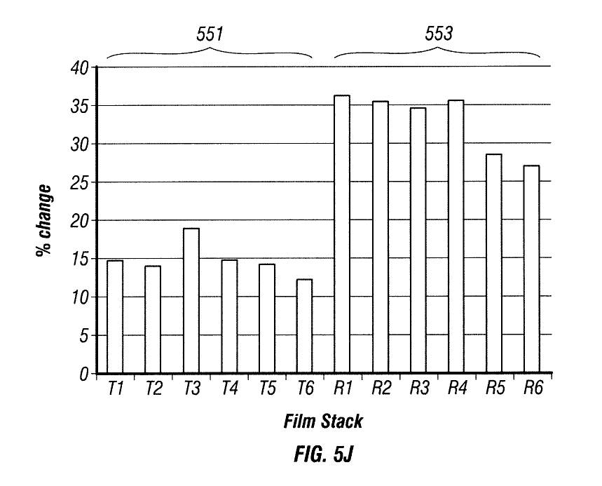

FIG. 5A is a diagram showing the spectral responses of various materials across a range of wavelengths from about 400 nm to 1400 nm. In this diagram, the y-axis is the spectral response of the material at a certain wavelength in terms of amps/watt of incident energy. The diagram shows the spectral responses of GaInP 513, α-Si 511, CdTe 505, GaAs 507, InP 515, polycrystalline silicon 501, monocrystalline silicon 509, and ZnO/CIGS 503. As can be appreciated by the diagram, PV materials have spectral responses that indicate significant power generation in the infrared spectrum.

FIG. 5B is a diagram showing the spectral response of a silicon photovoltaic cell 519 compared with the approximate solar power available at sea level 517 and the overall photovoltaic response in sunlight 521 across a range of wavelengths from about 300 nm to 1200 nm. As can be appreciated by the diagram, after allowing for the spectrum of sunlight, the overall spectral response of a silicon photovoltaic cell extends well into the infrared spectrum. Thus, a color filter, for example the filter shown in FIG. 4A, with a high reflection at a desired visible color and high transmission at longer wavelengths may be placed over a silicon photovoltaic cell to “color” the photovoltaic cell while still allowing useful energy collection at other wavelengths (e.g., longer wavelengths). As discussed in the foregoing text, an IMOD color filter using Si, or other photovoltaic material semiconductors, as the partial reflector layers will provide this characteristic.

FIG. 5C is a diagram showing the transmission of light energy 523 through an interferometric stack configured as shown in FIG. 4A. This embodiment includes a 50 Åt thick molybdenum first partial reflector, an 1800 Å thick optical resonant cavity comprising silicon dioxide, a 60 Å thick aluminum second partial reflector, and a glass substrate. As illustrated in FIG. 5C, transmission is reduced at wavelengths lower than about 950 nm and is less than about 20% in this particular embodiment (excluding reflection at the substrate surface).

FIG. 5D is a diagram showing the reflectance of light energy 525 from the substrate side of an interferometric modulator configured as shown in FIG. 4A. This embodiment includes a 50 Å thick molybdenum first partial reflector, an 1800 Å thick optical resonant cavity comprising silicon dioxide, a 60 Å thick aluminum second partial reflector, and a glass substrate. As illustrated in FIG. 5D, the reflection peak for this particular IMOD is about 50% at a wavelength of about 600 nm.

FIG. 5E is a CIE 1931 chromaticity diagram depicting the color reflected from the substrate side of an IMOD color filter configured as shown in FIG. 4A as the thickness of the spacer layer is varied. The IMOD color filter includes a 70 Å thick amorphous silicon first partial reflector, a 70 Å thick amorphous silicon second partial reflector, a polyethylene terephthalate substrate, and an optical resonant cavity comprising silicon dioxide that is varied between about 1000 Å and about 4650 Å thick. The color reflected from the substrate side of the PV cell as the thickness of the spacer layer is varied is shown by series 527. To create series 527, the thickness of the spacer layer was varied from about 1000 Å to about 4650 Å. As can be appreciated by the series representing the reflected light 527, an IMOD color filter configured as shown in FIG. 4A is capable of reflecting a wide range of colors.

FIG. 5F is a diagram showing the reflectance of light energy 531 from the substrate side of an interferometric modulator configured as shown in FIG. 4A. This embodiment includes a 70 Å thick first partial reflector comprising amorphous silicon, a 1500 Å thick spacer layer comprising silicon dioxide, a 70 Å thick second partial reflector comprising amorphous silicon, and a polyethylene terephalate substrate. As illustrated in FIG. 5F, the reflection peak for this particular IMOD is about 35% at a wavelength about 460 nm. Thus, the IMOD used to create FIG. 5F may produce a relatively bright reflection across the visible light spectrum.

FIG. 5G is a diagram showing the transmission of light energy 533 through an IMOD stack configured as shown in FIG. 4A. This embodiment includes a 70 Å thick first partial reflector comprising amorphous silicon, a 1500 Å thick spacer layer comprising silicon dioxide, a 70 Å thick second partial reflector comprising amorphous silicon, and a polyethylene terephalate substrate. As illustrated in FIG. 5G, the maximum transmission peak is above about 95% (excluding reflection at the substrate surface) at a wavelength of about 950 nm. Thus, the IMOD used to create FIGS. 5F and 5G reflects relatively bright colors in the visible spectrum and transmits more electromagnetic waves at longer wavelengths in the infrared spectrum. Considering the spectral response of various PV materials in FIG. 5A and the spectral response of Si in FIG. 5B, the IMOD configuration used to create FIG. 5G may be used to affect the color of a photovoltaic device while still transmitting useful longer electromagnetic waves to photovoltaic active materials for energy production.

FIG. 5H is a diagram showing the two curves that depict the upper and lower transmission values of light energy through an IMOD stack of one embodiment, for example, as configured as shown in FIG. 4A. This embodiment includes a 70 Å thick first partial reflector comprising amorphous silicon, a 70 Å thick second partial reflector comprising amorphous silicon, a polyethylene terephalate substrate, and a spacer layer that is varied between about 1200 Å and about 4000 Å. Line 535 depicts the upper transmission value and line 536 depicts the lower transmission value. The transmission characteristics through the IMOD stack will always lie between line 535 and line 536. As can be seen in FIG. 5H, the upper transmission value 535 and the lower transmission value 536 are greater than about 68% (excluding reflection at the substrate surface) at wavelengths greater than about 800 nm for all spacers between about 1200 Å to about 4000 Å thick. Thus, the color reflected from the substrate side of the IMOD may be tuned by varying the spacer to reflect a broad range of colors while still transmitting more than 68% of wavelengths greater than 800 nm.

FIG. 5I is a diagram comparing the index of refractions and extinction coefficients of various materials across a range of wavelengths. The index of refraction of air is shown by line 541. The index of refraction of aluminum is shown by line 543 and the extinction coefficient of aluminum is shown by line 537. The index of refraction of molybdenum is shown by line 549 and the extinction coefficient of molybdenum is shown by line 545. Additionally, the index of refraction of amorphous silicon is shown by line 547 and the extinction coefficient of amorphous silicon is shown by line 539. As can be seen in FIG. 5I, the extinction coefficient of amorphous silicon is less than 1.0 at wavelengths above about 520 nm and less than about 0.5 at wavelengths above about 700 nm. Thus, amorphous silicon is penetrated very easily by electromagnetic waves in the infrared spectrum. As discussed above with reference to FIG. 5B, the overall spectral response of a silicon photovoltaic cell extends will into the infrared spectrum.

FIG. 5J is a diagram comparing the negative change in peak power output from a sample PV cell covered with an interferometric stack according to one embodiment, for example, configured as shown in FIG. 4A. Series 551 shows the negative change in peak power output from the sample PV cell covered with an IMOD stack with a 70 Å thick Si first partial reflector and a 70 Å thick Si second partial reflector as the silicon dioxide spacer layer is varied between about 2350 Å and about 5100 Å. Series 553 shows the negative change in peak power output from the sample PV cell covered with an IMOD stack with a 140 Å thick Si first partial reflector and a 140 Å thick Si second partial reflector as the silicon dioxide spacer layer is varied between about 2350 Å and about 5100 Å. The partial reflectors in the IMOD stack used to create series 553 are more reflective and transmit less than the partial reflectors in the IMOD stack used to create series 551. As can be seen by FIG. 5J, the negative change in power output of a sample PV cell was only between about 15% and 35% when an IMOD color filter using silicon partial reflectors was added to the PV cell. Additionally, this negative change in output is less than an IMOD filter designed with a molybdenum first partial reflector and aluminum second partial reflector, which may reduce the output or efficiency of the same sample PV cell by about 75%. Accordingly, color filters incorporating IMOD filters or PV cells incorporating IMODs may be more efficient if the IMOD first and second partial reflectors comprise silicon, or similar materials.

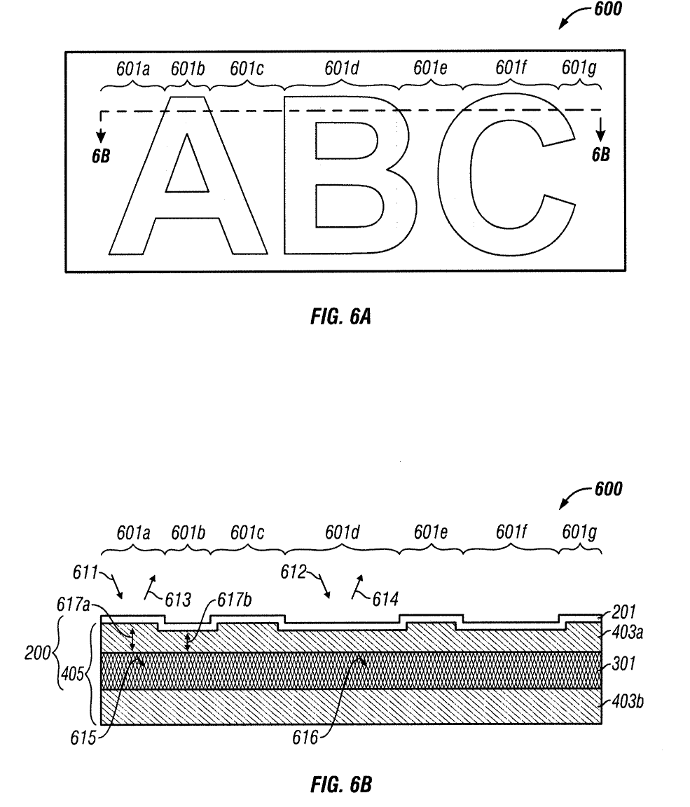

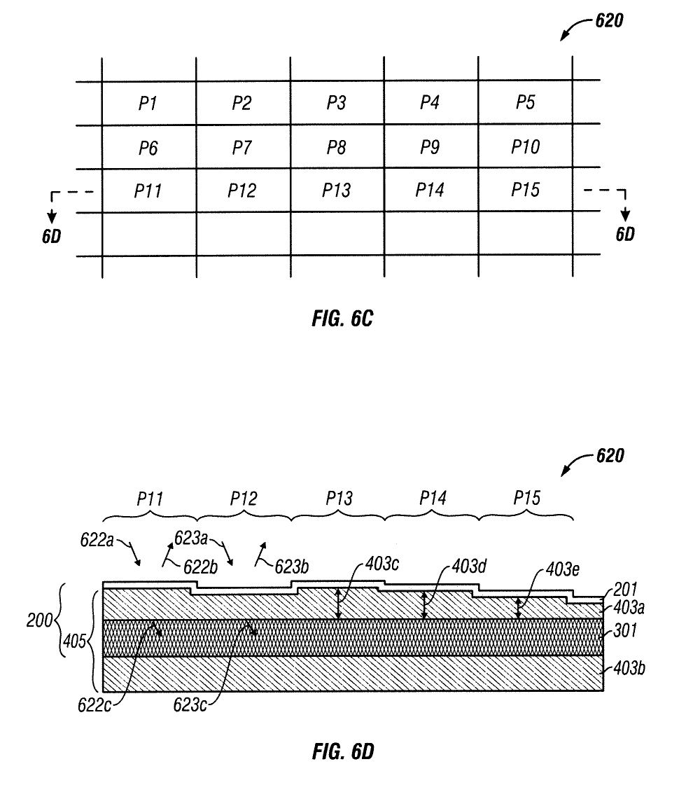

FIG. 6A depicts an embodiment of a PV device with different reflected colors in different regions, configured to display a particular image, shape, information, or characters as in a display, sign, or billboard. In FIG. 6A, a static display 600 contains multiple regions 601a-601g of uniform color. For example, the background (regions 601a, 601c, 601e, and 601g along cross-section 6B) may be yellow, red, green, or white or black. The letters “ABC” (regions 601b, 601d, and 601f in cross-section 6B) may be darker. For example, letters “ABC” may be blue.

FIG. 6B shows a cross section of a PV display device 600. As shown in FIG. 6B, light rays 611 and 612 incident upon the IMOD 200 are partly reflected as indicated by rays 613, 614, and partly transmitted along rays 615 and 616. In the illustrated cross-section, the IMOD 200 comprises a partial reflector layer 201, a first transparent conductive material layer 403a, and a PV active material layer 301. The PV active material layer 301 is disposed upon a second transparent conductive material layer 403b. The PV active material layer 301 and two transparent conductive material layers 403a,b comprise a PV cell 405. As shown in FIG. 6B, the thickness of the first optical resonant cavity layer 403a is not uniform. The first transparent conductive material layer 403a is patterned such that the IMOD 200 comprises multiple regions 601a-601g with different first optical resonant cavity layer 403a thicknesses corresponding to a different reflected color. As illustrated, the static display 600 comprises a first transparent conductive material layer 403a with two thicknesses corresponding to two different colors. However, the display 600 may comprise more than two thicknesses and thus more than two reflected interferometric display colors. As shown in FIG. 6B, regions 601a, 601c, 601e, and 601g have a relatively large first transparent conductive material layer 403a thickness 617a. On the other hand, regions 605b, 605d, and 605f have a smaller first transparent conductive material layer 403a thickness 617b. These different thicknesses are configured to result in reflections of different peaks (at different peak wavelengths) for reflected rays 613, 614. In this way, one region of the display will show one color, and another region will show a different color. In at least one of the regions, the IMOD 200 can be configured to reflect enough light so as to display a visible color, while also transmitting sufficient light to PV material layer 301 to generate electricity. Hence while incident rays 611 and 612 are partly reflected in rays 613 and 614, sufficient light may be transmitted in at least one of rays 617 and 618 to allow for the generation of an electrical current in the photovoltaic active material layer 301. FIG. 6B depicts a thin film PV device. However, as will be appreciated by the skilled artisan, a PV device 600 may comprise a traditional PV active layer with front electrodes that may be situated between the first transparent conductive material layer 403a and the photovoltaic material layer 301. Similarly, those of skill in the art will appreciate that PV device 600 may comprise layers not shown here, for example, anti-reflective coatings, diffusers, or passivation layers over the PV active material layer 301 or IMOD 200. Also, the PV device 600 may comprise regions of continuous color variation, rather than distinct regions of uniform color. As will be readily appreciated by one of skill in the art, continuous color variation can be accomplished by continuously varying the thickness of the first transparent conductive material layer 403a or partial reflector layer 201.

FIGS. 6C and 6D depict another embodiment of a PV display device 620. In FIG. 6C, the image or pattern displayed on the PV display device 620 is pixilated such that any image is made up of multiple pixels P1-P15. Hence the image or pattern comprises a regular array of pixels as shown in FIG. 6C. As will be appreciated by one of skill in the art, pixilation may be convenient for the transfer of digital images onto a static IMOD as shown in FIG. 6C. FIG. 6D is a cross-section of FIG. 6C showing an embodiment of a pixilated PV display device 620. As illustrated, an IMOD 200 comprises a partial reflector layer 201, a first transparent conductive material layer 403a, and a PV active material layer 301. The first transparent conductive material layer 403a has a variable thickness patterned so as to form pixels. The PV active material layer 301 is disposed upon a second transparent conductive material layer 403b. The PV active material layer 301 and two transparent conductive material layers 403a,b comprise a PV cell 405. Each pixel P1-P15 may be formed by a region of a uniform interferometric sub-stack such that one pixel may be made up of a discrete partial reflector layer, transparent conductive material layer, and PV active material layer. For example, pixel P13 may be made up of the partial reflector layer 201, the PV active material layer 301, and first transparent conductive material layer 403c. The partial reflector layer 201, PV active material layer 301, and first transparent conductive material layers 403d,e similarly may form pixels P14 and P15 in the pixel array, respectively. As illustrated, first transparent conductive material layers 403a,b,c may have different thicknesses, resulting in different colored pixels. In other embodiments, such as in a region of uniform color, several adjacent first transparent conductive material layers may have roughly equal thicknesses.

Still referring to FIG. 6D, in an RGB scheme, pixels P1-P15 may comprise red pixels, green pixels, and blue pixels. More generally, a regular array of pixels may comprise a plurality of red pixels, a plurality of green pixels, and a plurality of blue pixels. Hence, for example, the first transparent conductive material layer 403c may form a red pixel, while first transparent conductive material layer 403d may form a green pixel, and first transparent conductive material layer 403e may form a blue pixel. Other color schemes are also possible, for example, CMY (cyan, magenta, yellow), RYB (red, yellow, blue), and VOG (violet, orange, green), among others. As shown in FIG. 6D, the thickness of the first transparent conductive material layers 403c,d,e is primarily varied to affect the color of reflected light. However, the partial reflector layer 201 thickness may also be varied from pixel to pixel, along with the first transparent conductive material layer 403a thickness. This allows flexibility to have any desirable color (hue) and shade (saturation and lightness) in any pixel, as the thickness of any or all of the partial reflector layer 201 or the first transparent conductive material layer 403a can be tailored as necessary.

As shown in FIG. 6D, light rays 622a, 623a incident upon pixels P11, P12 in pixilated IMOD 200 are partly reflected as indicated by rays 622b, 623b and partly transmitted along rays 622c, 623c. Reflected rays 622b, 623b may contain different wavelength distributions and hence may reflect or display different colors depending upon the height or thickness of the first transparent conductive material layer 403a for pixels P11 and P12. As mentioned above, to allow for effective electricity generation, the IMOD 200 may be configured to reflect enough light to display a color while allowing sufficient light to transmit to the photovoltaic active material layer 301 along rays 622c, 623c. To accomplish this objective, the partial reflector layer 201 may be chosen based on the extinction coefficient of the material. For example, the partial reflector layer 201 may comprise amorphous silicon.

FIGS. 7A-7C illustrate one example of a process for fabricating a PV device 730 (FIG. 7C) incorporating IMOD 200. The example employs depositing layers of thin film active material 301a,b (FIG. 7C). As illustrated in FIG. 7A, in one embodiment, a method of manufacturing such a device can comprise providing a PV cell 405a formed on a substrate 311 to create a starter stack 710. The PV cell 405a comprises a first transparent conductive material layer 403a, a first PV active material layer 301a, and a second transparent conductive material layer 403b. The starter stack 710 can be pre-tuned to reflect a certain color or wavelength when a reflector or partial reflector, for example, a second PV active material, is deposited on the second transparent conductive material layer 403b. The starter stack 710 may be tuned by adjusting the thicknesses of the second transparent conductive material layer and/or the first PV active material layer 301a.

Still referring to FIG. 7A, the manufacturing of starter stack 710 can begin with a substrate and layers deposited upon the substrate in sequence. The first photovoltaic active material layer 301a may be deposited by physical vapor deposition, chemical vapor deposition, electrochemical vapor deposition, or plasma-enhanced chemical vapor deposition as well as other methods known to those of skill in the art. As is known by those with skill in the art, PV active material layers comprising amorphous silicon layers may include one or more junctions with and/or p-doped silicon and may further comprise p-i-n junctions. Other appropriate materials for the first PV active material layer 301a include germanium (Ge), Ge alloys, and alloys like copper indium gallium selenide (CIGS), cadmium telluride (CdTe), as well as III-V semiconductor materials, or tandem multi-junction photovoltaic materials and films. III-V semiconductor materials include such materials as gallium arsenide (GaAs), indium nitride (InN), gallium nitride (GaN), boron arsenide (Bas). Methods of forming these materials are known to those having skill in the art. As an illustrative example, allows like CIGS can be formed by a vacuum-based process where copper, gallium, and indium are co-evaporated or co-sputtered then annealed with a selenide vapor to form the final CIGS structure. Non-vacuuming based alternative processes are also known to those of skill in the art. The stack 710 may be pre-formed to be one piece.

With reference to FIG. 7B, the method of fabricating a PV device 730 incorporating IMOD 200 can employ a second stack 720. The second stack 720 may comprise a second PV active material layer 301b and a third transparent conductive material layer 403c. The second stack 720 may be added to the pre-tuned starter stack 710 to create a PV device 730. The second stack 720 may be deposited on the second transparent conductive material side of the starter stack 710 layer by layer, in sequence.

Referring now to FIG. 7C, a PV device 730, according to one embodiment, is formed when second stack 720 is deposited upon starter stack 710 layer by layer. For example, a third party may supply a quantity of starter stacks 710 to a PV device manufacturer and the PV device manufacturer may then form second stacks 720 on starter stacks 710 by depositing a second PV active material layer 301b upon starter stack 710 and then depositing a third transparent conductive material layer 403c upon the second PV active material layer 301b resulting in a PV device 730. In another embodiment, the PV device 730 may be manufactured in a monolithic process. PV device 730 is configured to reflect a certain color based on the thicknesses of the second transparent conductive material layer 403b and the thicknesses of the first and second PV active material layers 301a,b.

Still referring to FIG. 7C, PV device 730 comprises two PV cells 405a,b. Each of the PV cells 405a,b comprise a PV active material layer. The first PV cell 405a comprises a first PV active material layer 301a and the second PV cell 405b comprises a second PV active material layer 301b. Both the first and second PV active material layers 403a,b serve as partial reflector layers in IMOD 200. Thus, PV device 730 produces power and is configured to reflect a certain color from the substrate side of the device.

FIGS. 7D-7E illustrate another example of a process of fabricating a PV device 750 (FIG. 7E) incorporating an IMOD 200. As illustrated in FIG. 7D, in one embodiment, a method of manufacturing such a device can comprise providing a starter stack 740. The starter stack 740 may comprise a partial reflector 201 disposed between a substrate 311 and a first transparent conductive material layer 403a. The starter stack 740 can be pre-tuned to reflect certain wavelengths when a reflector or partial reflector, for example, a PV active material, is deposited on the first transparent conductive material layer 403a. The starter stack 740 may be tuned by adjusting the thicknesses of the first transparent conductive material layer 403a and/or the partial reflector 201. The material chosen for the partial reflector 201 may have a low extinction coefficient at wavelengths above about 800 nm to allow transmission of longer wavelengths through the starter stack 740.

Referring now to FIG. 7E, a PV device 750, according to one embodiment, is formed when second stack 720 is deposited upon starter stack 740 layer by layer. For example, a third party may supply a quantity of starter stacks 740 to a PV manufacturer. The PV device manufacturer may then form second stacks 720 on starter stacks 740 by depositing a PV active material layer 301 upon the starter stack 740 and then depositing a second transparent conductive material layer 403b upon the PV active material layer 301 forming a PV device 750. In another embodiment, the PV device 750 may be manufactured in a monolithic process. PV device 750 is configured to reflect a certain color from the substrate 311 side of the device and produce power.

FIG. 7F is a block diagram depicting a method 700 of manufacturing a PV device comprising one IMOD and two PV cells, according to one embodiment. Method 700 includes the steps of depositing a first transparent conductive material layer upon a substrate 701, depositing a first PV active material layer upon the first transparent conductive material layer 703, depositing a second transparent conductive material layer upon the first partial reflector layer 705, depositing a second PV active material layer upon the second transparent conductive material layer 707, and depositing a third transparent conductive material layer upon the second partial reflector layer 709. Performing the method 700 will form a PV device resembling the device shown in FIG. 4G. Each step may be adjusted in order to reflect a certain color from the substrate side of the formed PV device while maximizing energy production. For example, the first PV active material layer may comprise a material with a low extinction coefficient in the infrared spectrum and a higher extinction coefficient in the visible light spectrum. Examples of the material used for the first active material layer include Ge, GaInP, α-Si, CdTe, GaAs, InP, polycrystalline silicon, monocrystalline silicon, ZnO, and CIGS.

The foregoing description details certain embodiments of the invention. It will be appreciated, however, that no matter how detailed the foregoing appears in text, the invention can be practiced in many ways. As is also stated above, it should be noted that the use of particular terminology when describing certain features or aspects of the invention should not be taken to imply that the terminology is being re-defined herein to be restricted to including any specific characteristics of the features or aspects of the invention with which that terminology is associated. The scope of the invention should therefore be construed in accordance with the appended claims and any equivalents thereof.

What is claimed is:

1. A color filtering device comprising:
a first partial reflector layer comprising a material having an extinction coefficient that is less than about one (1) at wavelengths greater than about 800 nm;
a second partial reflector layer comprising a material having an extinction coefficient that is less than about one (1) at wavelengths greater than about 800 nm; and
a first optical resonant cavity defined by the first partial reflector layer and the second partial reflector layer.

2. The device of claim 1, further comprising a photovoltaic active layer disposed such that the second partial reflector layer is positioned between the first optical resonant cavity and the photovoltaic active layer.

3. The device of claim 1, further comprising a photovoltaic cell disposed such that the second partial reflector layer is positioned between the first optical resonant cavity and the photovoltaic cell.

4. The device of claim 3, further comprising an adhesive layer between the photovoltaic cell and the second partial reflector layer.

5. The device of claim 3, further comprising an elastomer layer between the photovoltaic cell and the second partial reflector layer.

6. The device of claim 1, wherein the first optical resonant cavity has a thickness between about 700 Å and about 5000 Å.

7. The device of claim 1, wherein a thickness of the first optical resonant cavity is not uniform across at least a portion of the color filtering device.

8. The device of claim 1, wherein the first partial reflector layer has a thickness between about 20 Å and about 300 Å.

9. The device of claim 8, wherein at least a portion of the first partial reflector and the second partial reflector are substantially the same thickness.

10. The device of claim 1, wherein the first partial reflector layer comprises material selected from the group consisting of Ge, GaInP, α-Si, CdFe, GaAs, InP, polycrystalline silicon, monocrystalline silicon, ZnO, and CIGS.

11. The device of claim 1, wherein the first and second partial reflector layers comprise a material having an extinction coefficient value that is less than about 1 at wavelengths greater than about 600 nm.

12. The device of claim 1, wherein the first and second partial reflector layers comprise a material having an extinction coefficient value that is less than about 0.5 at wavelengths greater than about 800 nm.

13. The device of claim 1, wherein the first and second partial reflector layers comprise a material having a lower extinction coefficient value for visible light than for infrared light.

14. The device of claim 1, wherein the first partial reflector layer and the second partial reflector layer comprise amorphous silicon.

15. The device of claim 1, wherein the first optical resonant cavity comprises a spacer layer.

16. The device of claim 15, wherein the spacer layer comprises silicon dioxide.

17. A color filtering device comprising:
a first means for partially reflecting light, the first partially reflecting means having an extinction coefficient that is less than about one (1) at wavelengths greater than about 800 nm;
a second means for partially reflecting light, the second partially reflecting means having an extinction coefficient that is less than about one (1) at wavelengths greater than about 800 nm; and
a first optical resonant cavity defined by the first partially reflecting means and the second partially reflecting means.

18. The device of claim 17, wherein the first means for partially reflecting light comprises a first partial reflector layer and the second means for partially reflecting light comprises a second partial reflector layer.

19. A photovoltaic device comprising:
a first partially reflective means, the first partially reflective means having an extinction coefficient that is less than about 1 at wavelengths greater than 800 nm;
a second partially reflective means, the second partially reflective means comprising a photovoltaic active material; and
a first optical resonant cavity defined by the first partial reflector layer and the second partial reflector layer.

20. The photovoltaic device of claim 19, wherein the first partially reflective means comprises a first partial reflector layer.

21. A photovoltaic device comprising:
a first partial reflector layer comprising a material having an extinction coefficient that is less than about 1 at wavelengths greater than 800 nm;
a second partial reflector layer comprising a photovoltaic active material; and
a first optical resonant cavity defined by the first partial reflector layer and the second partial reflector layer.

22. The device of claim 17, wherein the first optical resonant cavity has a thickness between about 700 Å and about 5000 Å.

23. The device of claim 17, wherein the first partial reflector layer has a thickness between about 20 Å and about 300 Å.

24. The device of claim 17, wherein the second partial reflector layer comprises material selected from the group consisting of Ge, GaInP, α-Si, CdTe, GaAs, InP, polycrystalline silicon, monocrystalline silicon, ZnO, and CIGS.

25. The device of claim 17, wherein the first partial reflector layer comprises a material having an extinction coefficient value that is less than 1 at wavelengths greater than 600 nm.

26. The device of claim 17, wherein the first partial reflector layer comprises a material having an extinction coefficient value that is less than 0.5 at wavelengths greater than 800 nm.

27. The device of claim 17, wherein the first partial reflector layer comprises a material having a lower extinction coefficient value in the visible light spectrum than the infrared spectrum.

28. The device of claim 17, further comprising:
a reflector layer disposed such that the second partial reflector layer is between the reflector layer and the first optical resonant cavity; and
a second optical resonant cavity defined by the second partial reflector layer and the reflector layer.

29. The device of claim 28, wherein the reflector layer is a partial reflector.

30. The device of claim 28, wherein the second optical resonant cavity comprises a transparent conductive material.

31. A photovoltaic device comprising:
a first partial reflector layer comprising a photovoltaic active material having an extinction coefficient that is less than about 1 at wavelengths greater than 800 nm;
a second partial reflector layer comprising a photovoltaic active material; and
a first optical resonant cavity defined by the first partial reflector layer and the second partial reflector layer.

32. The device of claim 31, wherein the first optical resonant cavity comprises a spacer layer.

33. The device of claim 32, wherein the spacer layer comprises a transparent conductive material.

34. The device of claim 32, wherein the spacer layer comprises:
a first transparent conductive material layer;
a second transparent conductive material layer; and
a second optical resonant cavity defined by the first transparent conductive material layer and the second transparent conductive material layer.

35. The photovoltaic device of claim 34, wherein the second optical resonant cavity comprises a spacer layer.

36. The device of claim 35, wherein the spacer layer of the second optical resonant cavity comprises a nonconductive material.

37. The device of claim 33, further comprising:
a first transparent conductive material layer disposed such that the first partial reflector layer is positioned between the first transparent conductive material layer and the spacer layer; and
a second transparent conductive material layer disposed such that the second partial reflector layer is between the second transparent conductive material layer and the spacer layer.

38. A photovoltaic device comprising:
a first photovoltaic active material layer;
a second photovoltaic active material layer;
an optical resonant cavity disposed between the first photovoltaic active material layer and the second photovoltaic active material layer;
a first transparent conductive material layer disposed such that the first photovoltaic active material layer is between the first transparent conductive material layer and the optical resonant cavity; and
a second transparent conductive material layer disposed such that the second photovoltaic active material layer is between the second transparent conductive material layer and the optical resonant cavity.

39. The device of claim 31, wherein the optical resonant cavity comprises a transparent conductive material.

40. The device of claim 31, wherein the first photovoltaic active material layer comprises a material having an extinction coefficient that is less than about one (1) at wavelengths greater than about 800 nm.

41. The device of claim 31, wherein the optical resonant cavity comprises a plurality of layers.

42. A method of manufacturing a photovoltaic device, the method comprising:
depositing a first transparent conductive material layer on a substrate;
depositing a first photovoltaic active layer on the first transparent conductive material layer;
depositing a second transparent conductive material layer on the first photovoltaic active layer;
depositing a second photovoltaic active layer on the second transparent conductive material layer; and
depositing a third transparent conductive material layer on the second photovoltaic active layer.

43. The method of claim 35, wherein the first partial reflector layer comprises a material having an extinction coefficient that is less than about one (1) at wavelengths greater than about 800 nm.

44. The method of claim 35, further comprising:
depositing a reflector layer on the third transparent conductive material layer.

45. The method of claim 37, wherein the reflector layer comprises a partial reflector.

46. A photovoltaic device comprising:
a first partial reflector layer comprising a photovoltaic active material having an extinction coefficient that is less than about 1 at wavelengths greater than 800 nm;
a second partial reflector layer comprising a photovoltaic active material;
a first optical resonant cavity defined by the first partial reflector layer and the second partial reflector layer;
a reflector layer;
a second optical resonant cavity comprising a transparent conductive material, the second optical resonant cavity defined by the second partial reflector layer and the reflector layer; and
a transparent conductive material layer disposed such that the first partial reflector layer is between the transparent conductive material layer and the first optical resonant cavity.

47. A photovoltaic device comprising:
a color filter comprising a first partial reflector and a transparent conductive material layer disposed on the first partial reflector; and
a photovoltaic active material layer disposed on the transparent conductive material layer.

48. A method of manufacturing a photovoltaic device, the method comprising:
providing a starter stack having a front side and a back side, the starter stack comprising a first partial reflector; and
depositing a photovoltaic active layer on the back side of the starter stack.

49. The method of claim 48, wherein the starter stack comprises a transparent conductive material layer disposed such that the first partial reflector is between the transparent conductive material layer and the front side of the starter stack.

50. The method of claim 44, wherein the starter stack comprises a transparent conductive material layer and spacer layer disposed such that the transparent conductive material layer and spacer layer are between the partial reflector and the back side of the starter stack.

51. The method of claim 48, wherein the first partial reflector comprises a material having an extinction coefficient that is less than about one (1) at wavelengths greater than about 800 nm.
